(19) United States
(12) Patent Application Publication
(10) Pub. No.: US 2010/0288325 A1
(43) Pub. Date: Nov. 18, 2010

(54) THERMOELECRIC CONVERSION MODULE AND CONNECTOR FOR THERMOELECTRIC CONVERSION ELEMENT

(75) Inventor: Koh Takahashi, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: UNIVERSAL ENTERTAINMENT CORPORATION, Tokyo (JP)

(21) Appl. No.: 12/863,811

(22) PCT Filed: Jan. 22, 2009
(86) PCT No.: PCT/JP2009/050968

§ 371 Date: Jul. 21, 2010

(30) Foreign Application Priority Data
Jan. 24, 2008 (JP) 2008-013481

(51) Int. Cl. H01L 35/30; H01R 13/02

(52) U.S. Cl. 136/205; 439/884

(57) ABSTRACT

Provided is a thermoelectric conversion module which can be flexibly applied to element size difference and thermal expansion of an element and has high electrical reliability with no conduction failure. A connector for a thermoelectric conversion element is also provided. A connector (C1) in one embodiment of this invention is provided for electrically connecting an electrode of a thermoelectric conversion element (30) to other electrode, and has an elastic deformation section (200) for adjusting the length of a connecting section (44) to be freely elongated and shortened.

### TECHNICAL FIELD

The present invention relates to a thermoelectric conversion module made by disposing thermoelectric conversion elements on a substrate, and electrically connecting an electrode of the thermoelectric conversion element with another electrode that is different from the electrode via a conductive connector of a predetermined shape, and a connector for a thermoelectric conversion element to electrically connect the electrode of the thermoelectric conversion elements to another electrode.

### BACKGROUND ART

Thermoelectric conversion indicates mutually converting heat energy and electric energy using the Seebeck effect and Peltier effect. If using thermoelectric conversion, it is possible to produce electric power from heat flow using the Seebeck effect, and it is possible to bring about a cooling phenomenon by way of heat absorption by flowing electric current to a material using the Peltier effect. This thermoelectric conversion does not cause excess waste product to be emitted during energy conversion due to being direct conversion, and further, has various characteristics in that the effective use of exhaust heat is possible, while maintenance is not necessary since moving devices such as a motor or turbine are not required, and thus has received attention as a high efficiency application technology of energy.

In thermoelectric conversion, normally an element of metal or a semiconductor called a thermoelectric conversion element is used, and one of a module structure has been known in which n-type semiconductor elements and p-type semiconductor elements are arranged alternately and like semiconductor elements that are adjacent are connected together by electrodes (e.g., refer to Japanese Unexamined Patent Application Publication No. H01-179376). In addition, one of a module structure has been known in which a plurality of semiconductor elements of the same conductivity type (more specifically, oxide thermoelectric conversion material of the same species), are provided to make a predetermined array, and like electrodes positioned on both sides of these semiconductor elements are made to be connected by lead wires (e.g., refer to WO2005/124881). In either of these structures, the structure arranged to be planar is basically made in a state in which the plurality of semiconductor elements of a plate shape is laid down to be horizontal.

### DISCLOSURE OF THE INVENTION

### Problems to be Solved by the Invention

However, the thermoelectric conversion module using the semiconductor disclosed in Japanese Unexamined Patent Application Publication No. H01-179376 forms a thermoelectric conversion module using p-type and n-type semiconductors of the same size in order to achieve an improvement in electrical output and an improvement in manufacturing simplicity. Therefore, elements different in size become scrap material, and as a result thereof, excess manufacturing costs increase and it also has an environmental burden. In addition, as is common technical knowledge, generally in semiconductor elements and modules using these semiconductor elements, thermal expansion occurs with higher temperatures, and the contact between the lead wire and the oxide thermoelectric conversion material easily becomes insufficient, as a result of this thermal expansion. In addition, if the contact is insufficient, a lack of electrical reliability results from conductance faults easily developing.

Furthermore, one of the module structure of WO2005/124881 made by connecting like electrodes of semiconductor elements with the same conductance type by lead wires devises the element structure by assembling single elements of the same material on a substrate in series, and thus achieves an improvement in thermoelectric conversion efficiency. However, due to being a structure in which a plurality of sintered bodies composed of complex metal oxide is affixed onto a substrate one-by-one in series, contact between the element and the lead wire can easily become insufficient, and thus there is fear of conductance faults occurring.

The present invention was made by focusing on the situation, and has as an object thereof to provide a thermoelectric conversion module and a connector for thermoelectric conversion elements that can flexibly deal with differences in element size and thermal expansion of elements, as well as having high electrical reliability without conductance faults.

### Means for Solving the Problems

In order to solve the problems, a thermoelectric conversion module according to a first aspect, which is made by disposing thermoelectric conversion elements on a substrate, and electrically connecting an electrode of the thermoelectric conversion element with an other electrode that is different from the electrode via a connector of a predetermined shape having electrical conductivity, includes an elastically deforming portion for extensibly adjusting a length thereof.

According to the thermoelectric conversion module as described in the first aspect, since an elastically deforming portion for extensibly adjusting the length of the connector is included, differences in element size can be absorbed by the elastically deforming portion, and connectors can be made to mechanically and electrically connect reliably to elements of various sizes (conductance faults associated with differences in element size can be prevented). In other words, even if elements differ in size, these elements can be handled without being discarded as waste material, and as a result, a reduction in manufacturing cost and a decrease in the environmental burden impact are possible compared to conventionally. In addition, since the elements can be easily detached from the connectors by way of the elastically deforming portion even when an element is damaged, it excels not only in ease of manufacturing, but also in maintenance properties. Furthermore, it is also not only possible to absorb differences in element size by the elastically deforming portion, but also deformation in the connector due to thermal expansion of elements, and thus electrical contact faults accompanying thermal expansion of elements can also be avoided.

It should be noted that, in the above configuration, “thermoelectric conversion element” is an element reciprocally converting heat energy and electrical energy employing the Seebeck effect and Peltier effect, and includes all of the structures (constitution) known conventionally. In addition, in the above configuration, silver, brass, SUS and the like, which do not easily rust in a high temperature oxidizing atmosphere, can be exemplified as the material of the connectors. Moreover, in the above configuration, the number of electrodes of the thermoelectric conversion element is arbitrary. Furthermore, in the above configuration, “other electrode” may be an electrode of another thermoelectric conversion element on the same substrate, for example, or may be an external electrode to which the thermoelectric conversion module is electrically connected.

In addition, according a thermoelectric conversion module according to a second aspect, in the thermoelectric conversion module as described in the first aspect, the elastically deforming portion is provided by forming the connector to bend.

According to the thermoelectric conversion module as described in the second aspect, as well as obtaining similar operational effects as the thermoelectric conversion module as described in the first aspect, it excels in workability and deformation and can easily realize deformation of the connector along with the size of elements differing and thermal expansion, since the elastically deforming portion takes a bent shape.

In addition, according to a thermoelectric conversion module according to a third aspect, in the thermoelectric conversion module as described in the first or second aspect, the elastically deforming portion is elastically deformable so as to absorb thermal expansion of the connector.

According to the thermoelectric conversion module as described in the third aspect, as well as obtaining similar operational effects as the thermoelectric conversion module as described in the first or second aspect, electrical contact faults accompanying thermal expansion of elements can be avoided and thus it excels in electrical reliability since deformation of the connector due to thermal expansion of elements can be absorbed by the elastically deforming portion.

In addition, according to a thermoelectric conversion module according to a fourth aspect, in the thermoelectric conversion module as described in any one of the first to third aspects, the connector further includes: a first fitting portion that is installed by fitting on an electrode of the thermoelectric conversion element; and a connector lead portion that is electrically connected to the first fitting portion and the other electrode.

According to the thermoelectric conversion module as described in the fourth aspect, as well as obtaining similar operational effects as the thermoelectric conversion module as described in any one of the first to third aspects, secure conduction can be obtained since a connector is used in which a conventional lead wire for connection and the fitting portion are integrated, and thus electrical reliability is improved. That is to say, in place of a conventional lead wire for connection, since a connector that can be said to integrally incorporate the lead wire is used and an electrode of a thermoelectric conversion element and another electrode are connected electrically by way of this connector, a thermoelectric conversion module can be provided having high electrical reliability without conduction failure.

In addition, according to a thermoelectric conversion module according to a fifth aspect, in the thermoelectric conversion module as described in the fourth aspect, the elastically deforming portion is provided to the connector lead portion.

According to the thermoelectric conversion module as described in the fifth aspect, as well as obtaining similar operational effects as the thermoelectric conversion module as described in the fourth aspect, deformation of the connector accompanying differences in sizes of elements and thermal expansion can be realized easily and effectively.

In addition, according to a thermoelectric conversion module according to a sixth aspect, in the thermoelectric conversion module as described in any one of the first to fifth aspects, each of the thermoelectric conversion elements contains the same material.

According to the thermoelectric conversion module as described in the sixth aspect, as well as obtaining similar operational effects as the thermoelectric conversion module as described in any one of the first to fifth aspects, it is possible to unify the electrical characteristics of each of the thermoelectric conversion elements by configuring the thermoelectric conversion elements from the same raw materials (e.g., same size, same shape, same materials (same conductivity type semiconductor, etc.)). As a result, it is possible to improve the thermoelectric conversion efficiency compared with conventional thermoelectric conversion modules made by disposing like elements having different conductivity type, for example, to be alternating. In addition, the elastically deforming portion, which is a characteristic constituent element of the present invention that aims to absorb differences in element size, is particularly more beneficial in a structure in which the same type of like raw materials are combined such as those disclosed in WO2005/124881 described above in which a few differences in element sizes do not cause a large effect on electrical characteristics, rather than a structure combining different types (p-type and n-type) of elements such as in Japanese Unexamined Patent Application Publication No. H01-179376 described above in which element size participates in electrical characteristics.

In addition, according to a thermoelectric conversion module according to a seventh aspect, in the thermoelectric conversion module as described in any one of the first to sixth aspects, the thermoelectric conversion element includes a principal surface having the largest surface area, while electrode are respectively positioned at both sides of the principal surface, and is disposed to be standing vertically so that the electrodes are opposing the substrates and the principal faces are substantially perpendicular to the substrates.

According to the thermoelectric conversion module as described in the seventh aspect, as well as obtaining similar operational effects as the thermoelectric conversion module as described in any one of the first to sixth aspects, the dimension in the height direction of the thermoelectric conversion element is enlarged, element electrical resistance is raised, and electric current is suppressed by arranging the thermoelectric conversion elements in a vertically standing state, while electromotive force is raised and thus it is possible to obtain high thermoelectric conversion efficiency, since it is made easy to achieve a temperature differential between both ends of an element. (for details thereof, refer to the embodiment described below).

It should be noted that, in the above-mentioned configuration, the shape of the thermoelectric conversion element can be arbitrarily selected such as a polyhedron shape including a cylinder or rectangle (cube, etc.). Ultimately, so long as being a shape having a principal face with the largest surface area and electrodes positioned on both sides of the principal faces, and such that can be disposed to be standing vertically so that the electrodes are in contact with the substrate, and the principal face is perpendicular to the substrate, what kind of shape is not a concern.

In addition, according to a thermoelectric conversion module according to an eighth aspect, in the thermoelectric conversion module as described in any one of the first to seventh aspects, the connector is fixed in advance in a predetermined array on the substrate.

According to the thermoelectric conversion module as described in the eighth aspect, as well as obtaining similar operational effects as the thermoelectric conversion module as described in any one of the first to seventh aspects, since the connectors are fixed beforehand in a predetermined array on the substrate, it is possible to create a thermoelectric conversion module simply by only mounting the thermoelectric conversion elements by inserting to the first fitting portion of the connectors, whereby it is possible to reduce the assembly labor (manufacturing process) (improve assembly properties).

It should be noted that, in the above-mentioned configuration, it is preferred that the connector is formed with metal using a conventional lead wire, and that the installation width of the first fitting portion of the connector is set to be smaller than the width of the electrodes of the thermoelectric conversion element. If configured in this way, when the thermoelectric conversion element is fitted by pushing into the first fitting portion of the connector, the first fitting portion is elastically expanded and the electrodes of the thermoelectric conversion element can be installed in the first fitting portion of the connector in a one-touch fashion, and since the thermoelectric conversion element and the connector can join without a gap due to the characteristics of the metal used in the lead wire, it is beneficial in that no conduction faults or contact faults occur between the thermoelectric conversion element and the connector. In addition, in the configuration in which the installation width of the first fitting portion of the connector is set to be smaller than the width of the electrodes of the thermoelectric conversion element in this way, it is preferred that the first fitting portion is formed by a pair of fold strips and both edges of each fold strip is formed in a taper shape. When configured in this way, in addition to the above operational effects, mounting of the thermoelectric conversion element to the connector is made easy due to the fold strips being smoothly elastically expanded by way of pushing the thermoelectric conversion element from both edge sides of the fold strip to cause to slide into the first fitting portion along the taper shape thereof.

In addition, according to a thermoelectric conversion module according to a ninth aspect, in the thermoelectric conversion module as described in any one of the first to eighth aspects, the electrodes of the thermoelectric conversion element include a pair of a first electrode and a second electrode that is positioned on both sides of the thermoelectric conversion element, and the thermoelectric conversion element is sandwiched between a first substrate opposing the first electrode and a second substrate opposing the second electrode.

According to the thermoelectric conversion module as described in the ninth aspect, as well as obtaining similar operational effects as the thermoelectric conversion module as described in any one of the first to eighth aspects, since the thermoelectric conversion elements are fixed by pressure being exerted from both sides by sandwiching the thermoelectric conversion elements with a pair of substrates, the contact surface area of the electrodes of the thermoelectric conversion element and the connector becomes large. As a result, it is possible to reduce conduction faults and contact faults, and thus the electrical reliability can be improved. It should be noted that, for this pair of substrates, it is preferred to use an insulative substrate such as an alumina substrate, or a substrate imparted with an insulation property by depositing stainless (SUS) or the like by way of PVD (physical vapor deposition). This makes it possible to prevent short circuits from occurring due to electrical causes of like connectors being fitted beforehand in a predetermined array.

In addition, according to a thermoelectric conversion module according to a tenth aspect, in the thermoelectric conversion module as described in any one of the first to ninth aspects, the other electrode is an external electrode to which the thermoelectric conversion module is electrically connected.

According to the thermoelectric conversion module as described in the tenth aspect, as well as obtaining similar operational effects as the thermoelectric conversion module as described in any one of the first to ninth aspects, it is possible to simply and securely perform connection with an external electrode by way of the connector, and it excels in incorporation to another apparatus, which can raise electrical reliability. That is to say, since the electrical connection between the thermoelectric conversion module and an external apparatus (another module, etc.) is made simply by fitting the first fitting portion to the thermoelectric conversion element and connecting the connector lead portion to the external electrode, the assembly properties are improved.

In addition, according to a thermoelectric conversion module according to an eleventh aspect, in the thermoelectric conversion module as described in any one of the fourth to tenth aspects, the first fitting portion includes a guiding portion that guides installation of the thermoelectric conversion element, and that is bendable so as to follow the thermoelectric conversion element after the thermoelectric conversion element has been installed in the first fitting portion.

According to the thermoelectric conversion module as described in the eleventh aspect, as well as obtaining similar operational effects as the thermoelectric conversion module as described in any one of the fourth to tenth aspects, the assembly efficiency can be improved since it becomes easy to mount the thermoelectric conversion elements to the connector (particularly, the effect in the case of setting the installation width of the fitting portion of the connector to be smaller than the width of the electrodes of the thermoelectric conversion element is great) by the first fitting portion having a guiding portion. In addition, by the guiding portion being able to fold so as to follow the thermoelectric conversion element, it is possible to fix the thermoelectric conversion element with the guiding portion after mounting the thermoelectric conversion element to the connector, and thus the mounting stability of the thermoelectric conversion element to the connector can be improved. Therefore, a thermoelectric conversion module can be provided having high electrical reliability without conductance faults.

In addition, according to a thermoelectric conversion module according to a twelfth aspect, in the thermoelectric conversion module as described in any one of the fourth to eleventh aspects, the first fitting portion includes a strip for short-circuiting that is bendable and has sufficient length to electrically connect with a connector adjacent thereto when bent.

According to the thermoelectric conversion module as described in the twelfth aspect, as well as obtaining similar operational effects as the thermoelectric conversion module as described in any one of the fourth to eleventh aspects, by the first fitting portion including a strip for short-circuiting, it is possible to easily repair by causing to conduct between connectors using the strip for short-circuiting, even in a case where a conduction fault has occurred between connectors due to damage to the thermoelectric conversion element itself or degradation of the thermoelectric conversion element.

In addition, according to a thermoelectric conversion module according to a thirteenth aspect, in the thermoelectric conversion module as described in any one of the fourth to twelfth aspects, the connector lead portion has a second fitting portion that is installed by fitting to an other electrode of an other thermoelectric conversion element disposed on the substrate.

According to the thermoelectric conversion module as described in the thirteenth aspect, as well as obtaining similar operational effects as the thermoelectric conversion module as described in any one of the fourth to twelfth aspects, since the connector lead portion has a second fitting portion that is installed by fitting to the other electrode of another thermoelectric conversion element disposed on the substrate, it is possible to electrically connect like thermoelectric conversion elements by way the connector on the substrate. That is to say, in place of a conventional lead wire for connections, a thermoelectric conversion module can be provided having high electrical reliability without conductance faults since a connector such that the lead wire is built in to be integrated is used, and like electrodes of thermoelectric conversion elements are electrically connected by way of this connector.

In addition, according to a thermoelectric conversion module according to a fourteenth aspect, in the thermoelectric conversion module as described in any one of the fourth to thirteen aspects, the connector lead portion has a parallel portion on a side face between electrode faces of the thermoelectric conversion element that extends from the electrode face.

According to the thermoelectric conversion module as described in the fourteenth aspect, as well as obtaining similar operational effects as the thermoelectric conversion module as described in any one of the fourth to thirteenth aspects, the contact surface area between the thermoelectric conversion element and the connector lead portion becomes large by the connector lead portion having a parallel portion, and the thermoelectric conversion elements can be retained with a larger surface area, whereby it is possible to improve the mounting stability of the thermoelectric conversion element in the connector.

In addition, according to a thermoelectric conversion module according to a fifteenth aspect, the thermoelectric conversion module as described in any one of the first to fourteenth aspects includes a fixing member having comb-teeth that can be inserted into both sides of the thermoelectric conversion element and have an electrical insulating property.

According to the thermoelectric conversion module as described in the fifteenth aspect, as well as obtaining similar operational effects as the thermoelectric conversion module as described in any one of the first to fourteenth aspect, by providing a fixing member including comb-teeth, the comb-teeth are inserted into both sides of one or a plurality of thermoelectric conversion, the thermoelectric conversion elements are supported also by way of the comb-teeth, and thus it is possible to improve the mounting stability of the thermoelectric conversion elements in the module.

In addition, the fixing member preferably possesses an electrical insulating property in order for short-circuit prevention. For example, in the case of mounting the fixing member to the cooling face side (low temperature side), an anodization treatment of aluminum (alumite treatment) is conducted on the fixing member, and in the case of mounting the fixing member on the heating face side (high temperature side), depositing stainless (SUS) to the fixing member by way of PVD (physical vapor deposition), and glass coating are preferred.

In addition, according to a thermoelectric conversion module according to a sixteenth aspect, in the thermoelectric conversion module as described in any one of the first to fifteenth aspects, the electrodes of the thermoelectric conversion element include a pair of a first electrode and a second electrode positioned on both sides of the thermoelectric conversion element, and one among the first electrode and the second electrode is defined as a heating face and the other is defined as a cooling face, and electricity is generated by way of a temperature differential between the heating face and the cooling face.

According to the thermoelectric conversion module as described in the sixteenth aspect, as well as obtaining similar operational effects as the thermoelectric conversion module as described in any one of the first to fifteenth aspects, it is possible to heat the substrate, and convert heat energy absorbed from the substrate into electrical energy by cooling the cooling face of the thermoelectric conversion elements.

In addition, according to a thermoelectric conversion module according to a seventeenth aspect, in the thermoelectric conversion module as described in any one of the first to sixteenth aspects, the thermoelectric conversion element is a sintered compact containing a complex metal oxide.

According to the thermoelectric conversion module as described in the seventeenth aspect, as well as obtaining similar operational effects as the thermoelectric conversion module as described in any one of the first to sixteenth aspects, it is possible to improve the heat resistance and mechanical strength by configuring the thermoelectric conversion elements with a sintered body of a complex metal oxide.

In addition, according to a thermoelectric conversion module according to an eighteenth aspect, in the thermoelectric conversion module as described in the seventeenth aspect, the complex metal oxide includes an alkali earth metal, a rare earth element, and manganese as constituent elements.

According to the thermoelectric conversion module as described in the eighteenth aspect, as well as obtaining similar operational effects as the thermoelectric conversion module as described in the seventeenth aspect, it is possible to further improve the heat resistance at high temperature by making an oxide of the complex metal elements be an oxide in which alkali earth metal, rare earths, and manganese are the constituent elements.

It should be noted that using calcium as the alkali earth metal is preferred, and using yttrium or lanthanum as the rare earth element is preferred. More specifically, a perovskite-type CaMnO₃ complex oxide is exemplified. The perovskite-type CaMnO₃ complex oxide is more preferably that represented by the general formula Ca₍₁₋ₓ)MₓMnO₃ (M is yttrium or lanthanum, and x is in the range of 0.001 to 0.05).

In addition, according to a thermoelectric conversion module according to a nineteenth aspect, in the thermoelectric conversion module as described in any one of the thirteenth to eighteenth aspects, the first fitting portion or the second fitting portion has an engaging portion of a hook shape that is engaged to a fixing groove of the thermoelectric conversion element.

According to the thermoelectric conversion module as described in the nineteenth aspect, as well as obtaining similar operational effects as the thermoelectric conversion module as described in any one of the thirteen to eighteenth aspects, mounting stability can be improved and a thermoelectric conversion module can be provided having high electrical reliability without conduction faults, since the thermoelectric conversion elements are firmly mounted to the connectors by way of the fitting portions of the connectors engaging a fixing groove of the thermoelectric conversion elements.

It should be noted that a connector for thermoelectric conversion elements having the characteristic configuration described above can also be provided by the present invention.

### EFFECTS OF THE INVENTION

According to the present invention, it is possible to provide a thermoelectric conversion module that can flexibly cope with differences in element size and thermal expansion of elements, as well as having high electrical reliability without conduction faults, and a connector for thermoelectric conversion elements.

### BRIEF DESCRIPTION OF THE DRAWINGS

FIG. 1 is a schematic diagram of a Seebeck coefficient measuring instrument;

FIG. 2 is a graph showing the measurement results for the resistivity of a plate sample;

FIG. 3 is a graph showing measurement results for the Seebeck coefficient of a plate sample;

FIG. 4 is a graph showing results for an power factor of a plate sample obtained from the resistivity and Seebeck coefficient shown in FIGS. 2 and 3;

FIG. 5 is a graph showing measurement results for the resistivity of a rod-shaped sample;

FIG. 6 is a graph showing measurement results for the Seebeck coefficient of a rod-shaped sample;

FIG. 7 is a graph showing results for an power factor of a rod-shaped sample obtained from the resistivity and Seebeck coefficient shown in FIGS. 5 and 6;

FIG. 8 is a heat conduction model illustration for illustrating the effects of element length on temperature differential;

FIG. 9 is a graph showing a relationship between element length and temperature differential;

FIG. 10 is a graph showing a relationship between element length and maximum generation output;

FIG. 11 shows calculation results for voltage, current, maximum generation output, etc. when the element shape is set flat and vertical;

FIG. 12A is a plan side view of an expanded state of a first connector for a thermoelectric conversion element used within the same array of thermoelectric conversion elements, FIG. 12B is a plan view of an expanded state of a second connector for thermoelectric conversion elements used between arrays that are adjoining, and FIG. 12C is a plan view of an expanded state of a third connector for thermoelectric conversion elements used between an array of thermoelectric conversion elements and an external electrode;

FIG. 13A is a perspective view showing a state in which like thermoelectric conversion elements that are adjoining in the same array are connected by the first connector for thermoelectric conversion elements, FIG. 13B is a front view of the first connector for thermoelectric conversion elements, and FIG. 13C is a side view of the first connector for thermoelectric conversion elements;

FIG. 14A is a side view showing behavior of an elastically deforming portion of the first connector relative to the thermoelectric conversion element having a smaller defined size, and FIG. 14B is a side view showing behavior of the elastically deforming portion of the first connector relative to the thermoelectric conversion element having a larger defined size;

FIG. 15A is a perspective view showing a state in which like thermoelectric conversion elements adjoining between adjacent arrays are connected with the second connector for thermoelectric conversion elements, FIG. 15B is a front view of the second connector for thermoelectric conversion elements, and FIG. 15C is a side view of the second connector for thermoelectric conversion elements;

FIG. 16A is a perspective view showing a state in which a third connector for thermoelectric conversion elements to be connected to an external electrode is fitted to a thermoelectric conversion element positioned first in an array, FIG. 16B is a front view of the third connector for thermoelectric conversion elements, and FIG. 16C is a side view for the third connector for thermoelectric conversion elements;

FIG. 17A is a perspective view showing a state in which the third connector to be connected to an external electrode is fitted to a thermoelectric conversion element positioned last in an array, FIG. 17B is a front view of the third connector for thermoelectric conversion elements, and FIG. 17C is a side view of the third connector for thermoelectric conversion elements;

FIG. 18 is a perspective view of a thermoelectric conversion module according to a first embodiment of the present invention configured by electrically connecting a plurality of thermoelectric conversion elements in a predetermined array using the first to third connectors for thermoelectric conversion elements;

FIG. 19 is a perspective view of a thermoelectric conversion element;

FIG. 20 is a cross-sectional view in which the first array is viewed from a direction perpendicular to an extending direction thereof;

FIG. 21 is a perspective view showing an aspect of slide mounting a thermoelectric conversion element to the first connector;

FIG. 22A is a plan view of an expanded state of a modified example of the third connector, and FIG. 22B is a perspective view of a bent state of the third connector of FIG. 22A;

FIG. 23 is a perspective view of a thermoelectric conversion module using the third connector of FIG. 22;

FIG. 24 is a schematic diagram showing a modified example of a connector;

FIG. 25 is a schematic diagram showing a modified example of a thermoelectric conversion element;

FIG. 26 shows another modified example of a connector, with FIG. 26A being a side view showing an aspect of slide mounting the thermoelectric conversion element to the connector, FIG. 26B being a side view showing a state in which the thermoelectric conversion element has been slide mounted to the connector, and FIG. 26C being a side view showing an aspect of bending a guiding portion of the connector in the state of FIG. 26B inwards;

FIG. 27 is a modified example of a mounting structure of a thermoelectric conversion element and connector, with FIG. 27A being a side view of the thermoelectric conversion element, FIG. 27B being a side view of the connector, and FIG. 27C being a side view of a state in which the thermoelectric conversion elements have been mounted to the connectors;

FIG. 28 shows yet another modified example of a connector, with FIG. 28A being a side view of a state in which thermoelectric conversion elements have been mounted to connectors having a planar portion, FIG. 28B being a plan view of a fixing member provided separately or in combination with the connector, FIG. 28C being a side view in which the fixing member in the state of FIG. 28A has been mounted, and FIG. 28D being a perspective view showing an aspect of mounting the fixing member from the state of FIG. 28A; and

FIG. 29 shows another different modified example of a connector, with FIG. 29A being a side view of the connector, and FIG. 29B being a state in which thermoelectric conversion elements have been mounted to the connectors.

### EXPLANATION OF REFERENCE NUMERALS

30 thermoelectric conversion element
30a, 30b principal face
30c, 30d electrode face
40, 42, 50, 52, 60 fitting portion
44, 54 connecting portion
64 connector lead portion
90 first substrate
91 second substrate
200, 202 elastically deforming portion
A1 first array
A2 second array
A3 third array
A4 fourth array
C1 first connector
C2 second connector
C3 (C3a, C3b) third connector
M thermoelectric conversion module

### PREFERRED MODE FOR CARRYING OUT THE INVENTION

A first embodiment of the present invention will be explained below with reference to the drawings.

The present inventors have examined the composition of thermoelectric conversion elements and the shape thereof, while making further increased output of thermoelectric conversion elements the objective.

First, CaCO₃, MnCO₃ and Y₂O₃ were added along with purified water into a mixing pot into which pulverizing balls had been placed, the mixing pot was mounted to an oscillating ball mill and vibrated for 2 hours, thereby mixing the contents of the mixing pot. Next, the mixture thus obtained was filtered, dried, and then the dried mixture was preliminarily calcined in an electric furnace for 5 hours at 1000° C. Next, the preliminarily calcined body thus obtained was pulverized with an oscillating mill, and the ground product was filtered and dried. Next, a binder was added to the ground product after drying, and then granulated by grading after drying. Thereafter, the granules thus obtained were molded in a press, and the compact thus obtained underwent main calcination in an electric oven for 5 hours. From this, a CaMnO₃ system thermoelectric conversion element was obtained as a sintered body.

In addition, in the above-mentioned method, 7 types of samples in which x of Ca₁₋ₓYₓMnO₃ were 0, 0.003, 0.006, 0.0125, 0.025, 0.05, and 0.10 were manufactured, and in the manufacture of each sample, the main calcination temperature was changed to 1100° C., 1200° C., and 1300° C. In addition, a plate sample with sides of about 8 mm and a thickness of about 2.5 mm, and a rod-shaped sample with a cross-section of about 2.5 mm×3 mm and a thickness of about 8 mm were prepared as samples.

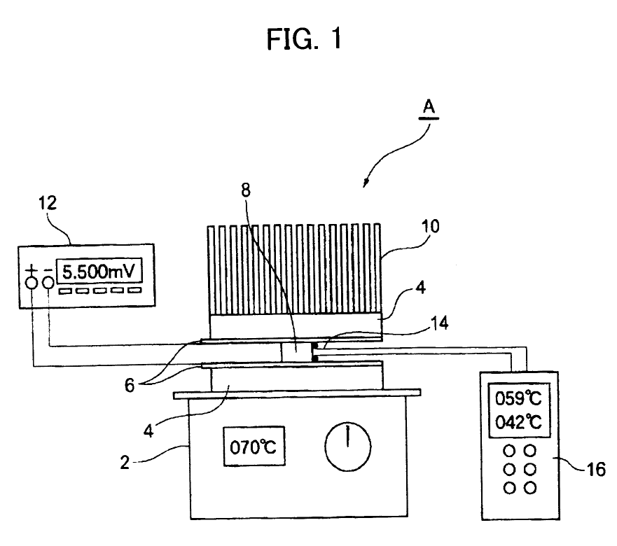

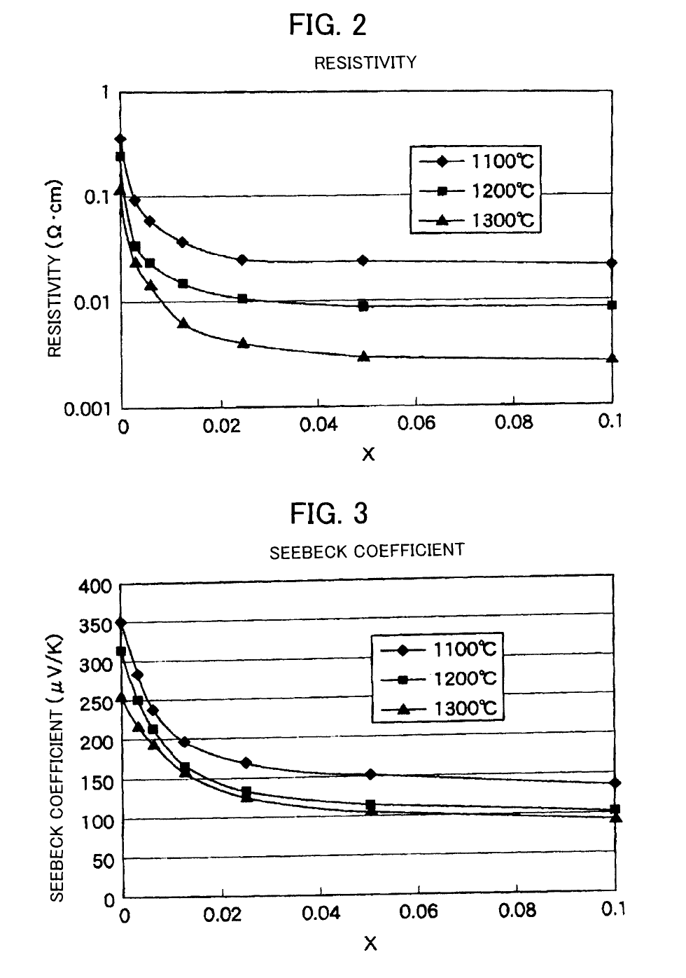

The resistivity ρ and Seebeck coefficient α were measured for the plate samples and rod-shaped samples obtained by changing the main calcination temperature for these 7 compositions. The resistivity ρ was measured by the four-terminal method using a digital voltmeter, and the Seebeck coefficient α was measured by way of the measurement device A shown in FIG. 1. The results thereof are shown in FIGS. 2 and 3.

It should be noted that, in the measurement device A shown in FIG. 1, a sample 8 is clamped in a pair of copper plates 6, 6 disposed on a hot plate 2 via an aluminum plate 4, and a heat sink 10 is disposed on the upper copper plate 6. In addition, a digital voltmeter 12 and a thermocouple 14 are connected to each of the pair of copper plates 6, 6, and the thermocouple 14 is connected to a digital thermometer 16.

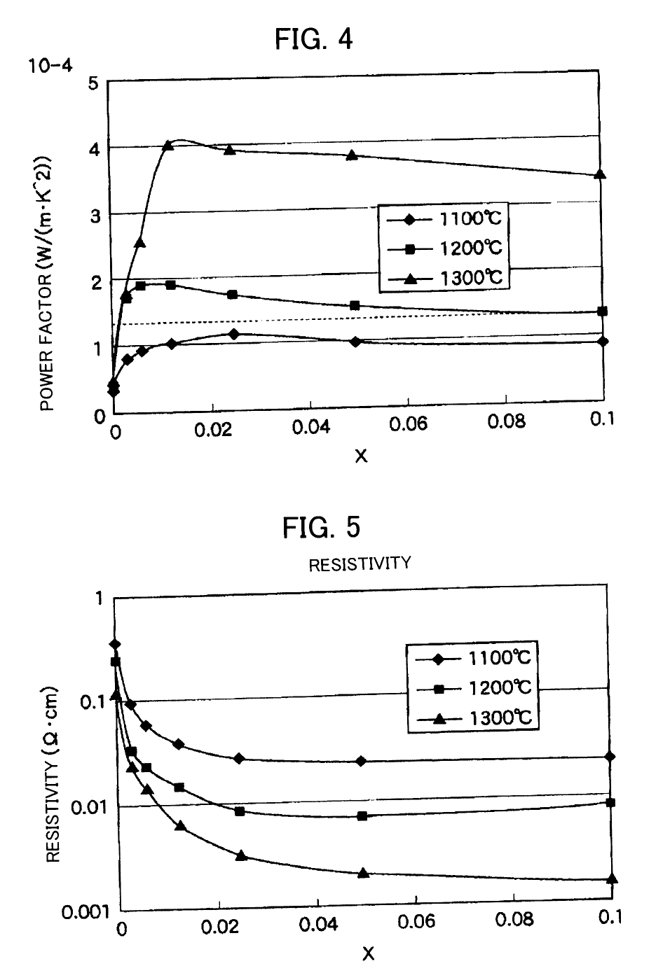

The resistivity ρ of the plate sample is as shown in FIG. 2, and the Seebeck coefficient α of the plate sample is as shown in FIG. 3. As shown in FIGS. 2 and 3, the resistivity ρ and the Seebeck coefficient α decreased along with the main calcination temperature becoming higher, and the x in the above-mentioned composition becoming larger. In addition, the power factor PF (=S²/ρ) was sought from the resistivity ρ and Seebeck coefficient α thus obtained. The results thereof are shown in FIG. 4. As is understood from FIG. 4, in the case of the x in the above-mentioned composition being 0.003 to 0.1 and the main calcination temperature being 1200° C., a power factor higher than the published value (Ohtaki, M. et al.; “(Ca_{0.9}Bi_{0.1})MnO₃),” J. Solid State Chem., 120 (1995)) was obtained. In addition, the power factor was the highest value of 4.02×10⁻⁴ W/(m·K²) in the case of the x in the above-mentioned composition being 0.0125 and the main calcination temperature being 1300° C.

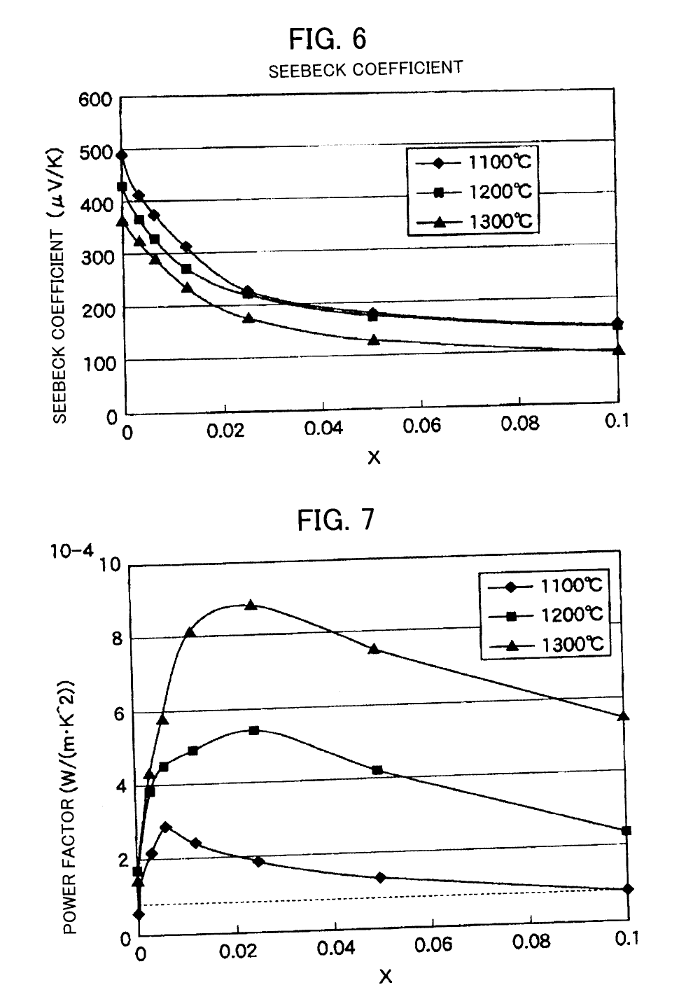

Furthermore, the resistivity ρ of the rod-shaped sample is as shown in FIG. 5, and the Seebeck coefficient α of the rod-shaped sample is as shown in FIG. 6. As shown in FIGS. 5 and 6, the slope along with an increase in the x of the above-mentioned composition is the same as that of the plate sample. Moreover, the Seebeck coefficient α was larger for the rod-shaped sample. Additionally, the resistivity ρ was substantially equal to that of the plate sample. In addition, the power factor PF (=S²/ρ) was sought from the resistivity ρ and Seebeck coefficient α thus obtained. The results thereof are shown in FIG. 7. As is understood from FIG. 7, in the case of the x in the above-mentioned composition being 0.025 and the main calcination temperature being 1300° C., a power factor approximately 7 times higher than the published value (Ohtaki, M. et al.; “(Ca_{0.9}B_{0.1})MnO₃),” J. Solid State Chem., 120 (1995)) of 8.85×10⁻⁴ W/(m·K²) was obtained.

In this way, it was found that the rod-shaped element possesses a higher power factor. As a result, manufacturing a thermoelectric conversion module using rod-shaped elements is considered to be preferable. Herein, a thermoelectric conversion module using rod-shaped elements is discussed.

The present inventors have previously applied for a patent regarding thermoelectric conversion modules using plate-shaped elements, and this has already been published (PCT International Publication No. WO05/124881 Pamphlet). In the invention of this official bulletin description, the cross-sectional area of the elements is made small in order to suppress heat transfer by lead wires connected to the elements as much as possible, and it is necessary to restrain the allowable current as well to be small as a result. Therefore, in such a module, when the temperature differential is at least 200° C., the current value is at least 10 A, and is considered to affect the lead wires.

Consequently, the present inventors have found that it is possible to raise the element resistance in the thermoelectric conversion module and control the current by using rod-shaped elements, which have a power factor as described above. In addition, as described later, it was found that the voltage can be raised to make achieving a temperature differential easy by setting the elements to be vertical, and it is possible to raise the power density by setting the thermal resistance to an appropriate value.

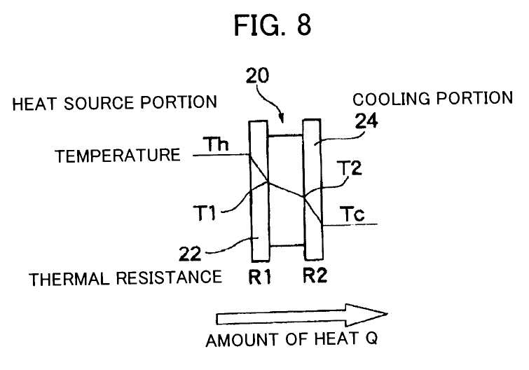

In relation to this, the effects on temperature differential due to element length will first be explained with reference to FIG. 8.

The temperature differential between both ends of an element when heat is introduced to the element is decided by the heat source temperature, cooling temperature, heat flow to the element and thermal resistance during emission, in addition to the thermal conductivity of the element and length of the element. In other words, as shown in FIG. 8, in a case where an element 20 is clamped in a pair of support plates 22 and 24, the heat source temperature Th drops to T1 due to the thermal resistance R1 when conducting through one of the support plates 22, and drops to T2 when conducting through the element 20, and further drops to Tc due to the thermal resistance R2 when conducting through the other support plate 24.

In this case, the amount of heat Q when conducting through the support plates 22 and 24, and the element 20 is expressed by the following formula (1).

Q={(Th−Tc)/(R1+l/k+R2)}·S Formula (1)

Here, k indicates the thermal conductivity, 1 indicates the length of the element 20, and S indicates the cross-sectional area. Therefore, the temperature differential T1-T2 of both ends of the element 20 is expressed by the following formula (2).

$$\begin{matrix}T 1 - T 2 = Q / S \cdot ( 1 / k ) \\ = \{ ( Th - Tc ) \cdot ( 1 / k ) \} / ( R 1 + 1 / k + R 2 )\end{matrix} \qquad Formula ( 2 )$$

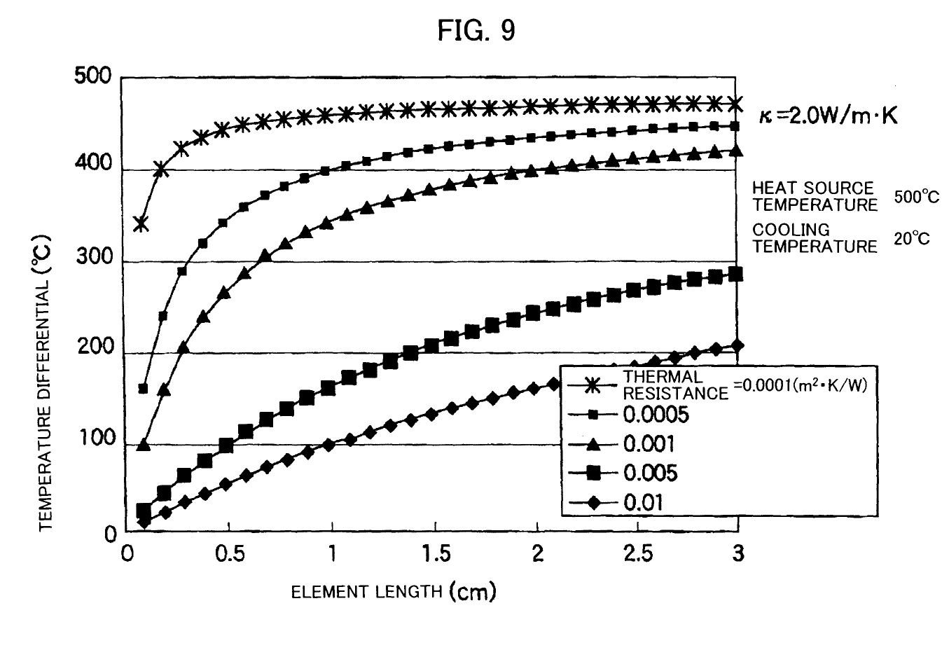

Using this formula (2), the temperature differential in relation to the length of the element 20 was sought. As conditions when searching, Th=500° C. and Tc=20° C. were set, the thermal conductivity of the element 20 was set to 2.0 W/m·K, and both of the thermal resistances R1 and R2 were changed in the range of 0.0001 to 0.01 m²/W·K. In addition, the length of the element 20 was set to 0.1 cm to 3.0 cm. The results thereof are shown in FIG. 9. As is understood from FIG. 9, the temperature differential increased with the length of the element becoming longer, and the thermal resistivity became smaller with increasing temperature differential. In addition, with a thermal resistivity of 0.01 m²/W·K, only a temperature differential of about 23° C. could be obtained at a length of the element being 0.2 cm, whereas at 0.0001 m²/W·K, a temperature differential of about 400° C. was obtained at a length of the element being 0.2 cm. From this result, it was understood that it is necessary to make the thermal resistivity as small as possible in order to increase the temperature differential.

Next, the effects on generation maximum output by the length of the element will be explained.

The generation maximum output Pmax of the thermoelectric conversion element is expressed by the following formula (3) according to thermoelectric force V and electrical resistance R of the element.

Pmax=(V²/R)/4 Formula (3)

In addition, the thermoelectric force V is expressed by the following formula (4) according to the Seebeck coefficient α and temperature differential ΔT of the thermoelectric conversion material.

V=α·ΔT Formula (4)

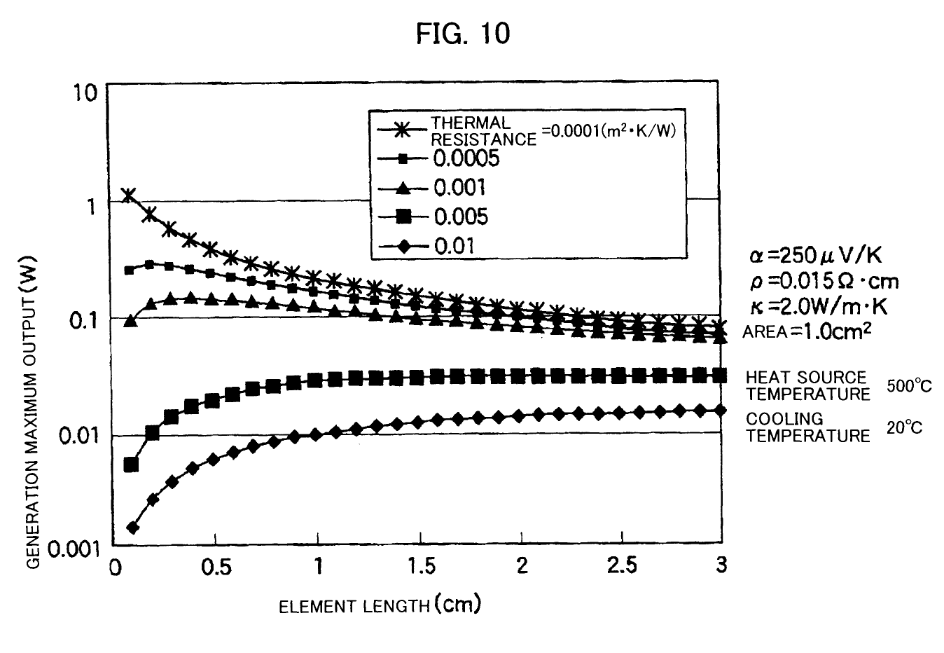

Herein, the temperature differential ΔT depends on the length of the element as described above, and thus is calculated for a generation maximum output relating to the length of the element. In this case, the Seebeck coefficient of the thermoelectric conversion material was set to 250 μV/K, the resistivity to 0.015Ω·cm, the thermal conductivity to 2.0 W/m·K, and the cross-sectional surface area of the element to 1.0 cm². Both of the thermal resistances R1 and R2 were changed in the range of 0.0001 to 0.01 m²/W·K. The results thereof are shown in FIG. 10. As is understood from FIG. 10, the generation maximum output changes according to the length of the element, and there is a length of the element that gives a maximum according to the heat resistance. In addition, it is understood that, with thermal resistance decreasing, the length of the element for which maximum output is obtained becomes lower. Furthermore, at a thermal resistance of 0.005 m²/W·K, the length of the element was found to be 2.0 cm, and at 0.001 m²/W·K, the length of the element was found to be 0.4 cm. Therefore, for thermal resistances in the range of 0.001 m²/W·K to 0.005 m²/W·K, the length of the element being 0.4 cm to 2.0 cm is considered appropriate.

Next, output characteristics due to a change in element shape will be explained.

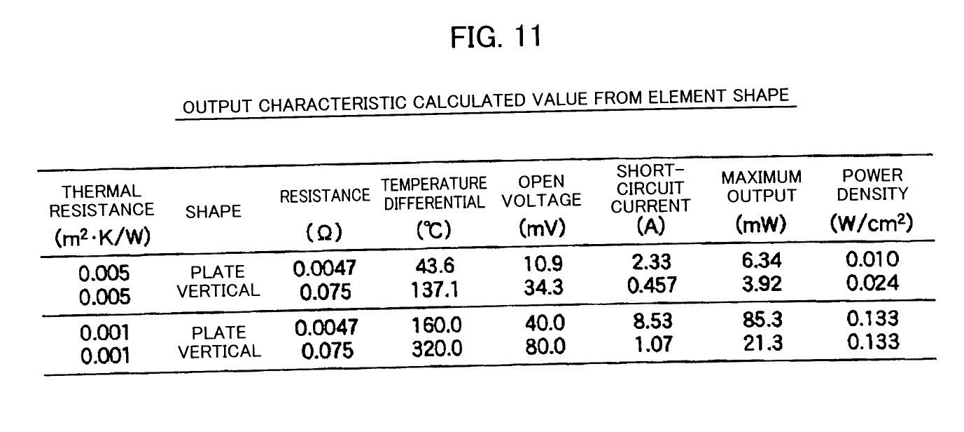

The voltage, current, and maximum generation output were examined with a plate-shaped element (8 mm×8 mm cross-section, 2 mm height, and a rod-shaped element (vertical) (8 mm×2 mm cross-section, 8 mm height). The results thereof are shown in FIG. 11. In this case, the heat source temperature was set to 500° C., the cooling temperature to 20° C., the Seebeck coefficient α of the thermoelectric conversion material to 250 μV/K, the resistivity to 0.015Ω·cm, and the thermal conductivity to 2.0 W/m·K.

As is understood from FIG. 11, since the element of a rod-shape have higher resistance, the open voltage is high and the short-circuit current is small. In addition, at the thermal resistance of 0.005 m²/W·K, the power density becomes larger than the element of plate shape.

In this way, it was understood that the rod-shaped element is more preferable in the aspect of output as a thermoelectric conversion element.

As a result, the present inventors found the necessity to arrange the thermoelectric conversion elements in a standing state in order to implement such rod-shaped elements, and thus devised a connector having good connectivity for a plurality of thermoelectric conversion elements in a standing state, and yet can connect efficiently and modularize. Hereafter, this will be explained in detail.

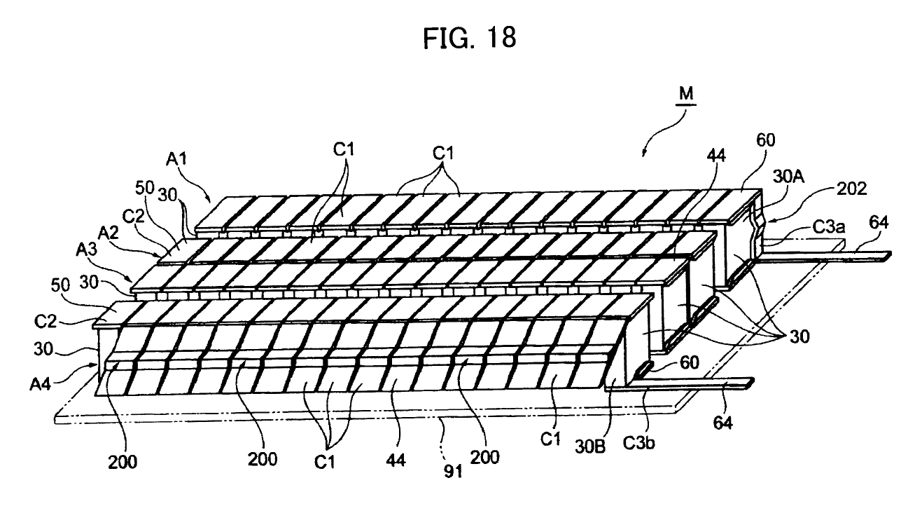

A thermoelectric conversion module M related to a first embodiment of the present invention configured by electrically connecting a plurality of thermoelectric elements 30 in predetermined arrays using first to third connectors for thermoelectric conversion elements C1, C2, and C3 of three types is shown in FIG. 18. As illustrated, the above-mentioned arrays of the thermoelectric conversion elements 30 includes first to fourth arrays A1, A2, A3, and A4, which extend in parallel to be mutually adjoining. In addition, 17 of the thermoelectric conversion elements 30 are connected in series in each of the arrays A1, A2, A3, and A4, while each of the like arrays A1 to A4 is connected in series. It should be noted that “thermoelectric conversion module” in the present specification is a module including thermoelectric conversion elements in which single elements are connected together by electrodes on a substrate, and other components (e.g., insulator).

Each of the thermoelectric conversion elements 30 constituting the thermoelectric conversion module M is an element that mutually converts heat energy and electric energy by utilizing the Seebeck effect and Peltier effect, and is composed of the same raw material. In other words, each of the thermoelectric conversion elements 30 are set to have a size (e.g., cross-section of about 2.5 mm×about 3 mm, and length of about 8 mm), shape, and materials (same conductive semiconductor) that are all the same. More specifically, in the present embodiment, each of the thermoelectric conversion elements 30 is a sintered body cell composed of a complex metal oxide, and contains an alkali earth metal, rare earth element and manganese as constituent elements. In particular, in the present embodiment, a CaMnO₃-based element is used for each of the thermoelectric conversion elements 30. It should be noted that, in the present embodiment, although an n-type semiconductor is used as the thermoelectric conversion element 30, it is not limited thereto.

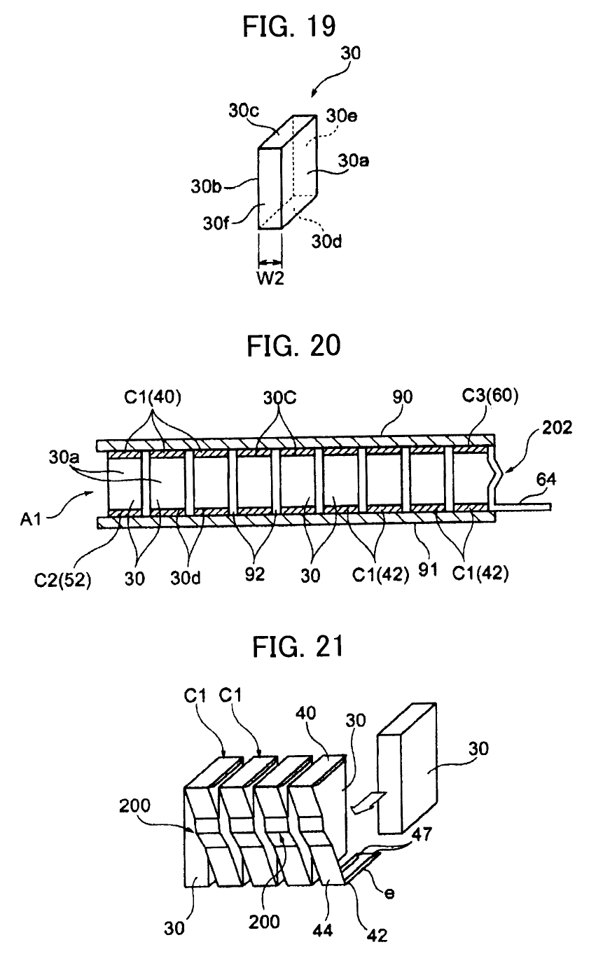

In addition, as shown in FIG. 19, each of the thermoelectric conversion elements 30 is made to be a rectangular solid, and includes a pair of principal faces 30a and 30b opposing each other and having the largest surface area, a pair of first and second electrodes (hereinafter referred to as first and second electrode faces due to be made level surfaces) 30c and 30d each positioned on both sides of these principal faces 30a and 30b, and two remaining side faces 30f, 30e. In this case, one among the first and second electrode faces 30c and 30d is defined as a heating face and the other is defined as a cooling face, and it is made so as to generate electricity according to the temperature differential between the heating face and the cooling face.

It should be noted that side faces 30f and 30e may be electrode faces. In addition, each of the thermoelectric conversion elements 30 is not rectangularly shaped, but rod-shaped, and may be made cylindrically-shaped in particular. In this case, the upper face and lower face of a cylindrical body are formed as electrode faces, and the side face is formed as a principal face.

In addition, in the present embodiment, the arrays A1 to A4 of the thermoelectric conversion elements 30 are sandwiched between a first substrate 90 opposing a first electrode face 30c of each of the thermoelectric conversion elements 30 and a second substrate 91 opposing a second electrode face 30d of each of the thermoelectric conversion elements 30, as clearly shown in FIG. 20. In this case, each of the thermoelectric conversion elements 30 is disposed to be standing vertically so that the electrode faces 30c and 30d are contacting the substrates 90 and 91 via the connectors C1, C2, and C3, and the principal faces 30a and 30b are substantially perpendicular to the substrates 90 and 91.

It should be noted that, so long as the substrate 91 is a material having insulation properties such as glass and wood, it is not particularly limited. In addition, in order to prevent electrical short-circuiting (shorting) between substrate-electrode and between electrode-electrode, it is preferred to provide insulation so as to cover between these or electrodes. In addition to installing insulation such as insulating paste containing a nitride such as alumina nitride (AlN) and an oxide such as silica (SiO₂), such insulation can be attained also by conducting an insulating treatment such as anodization treatment to the lead wire.

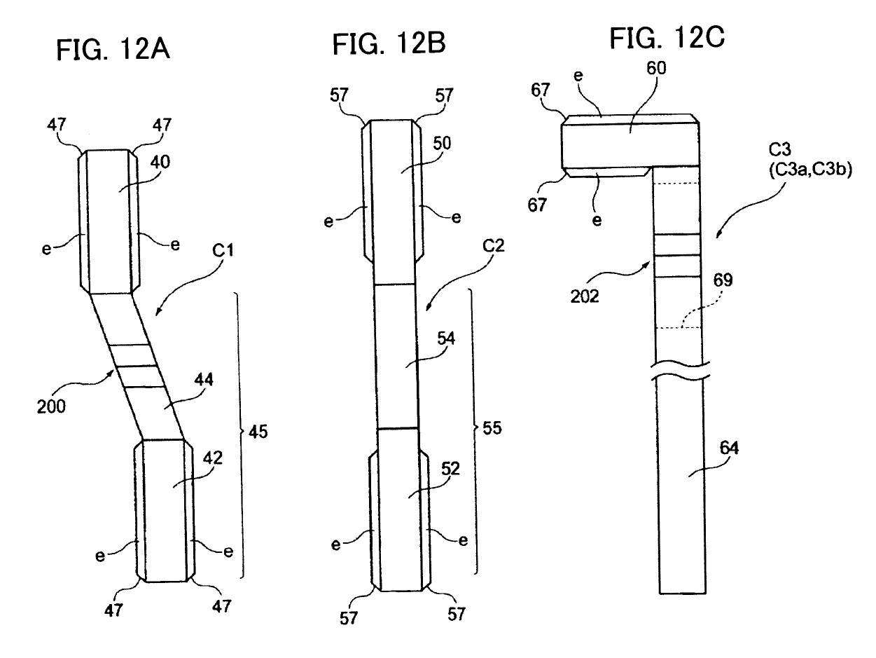

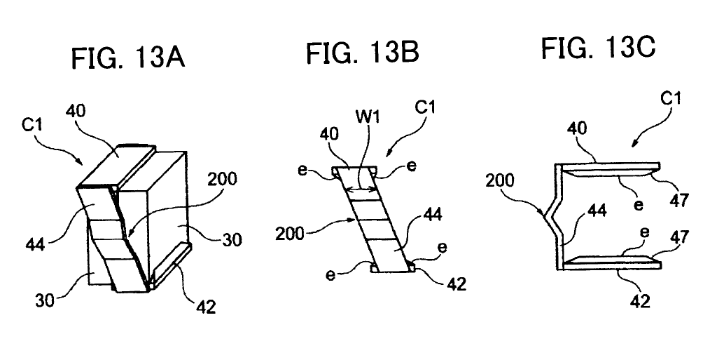

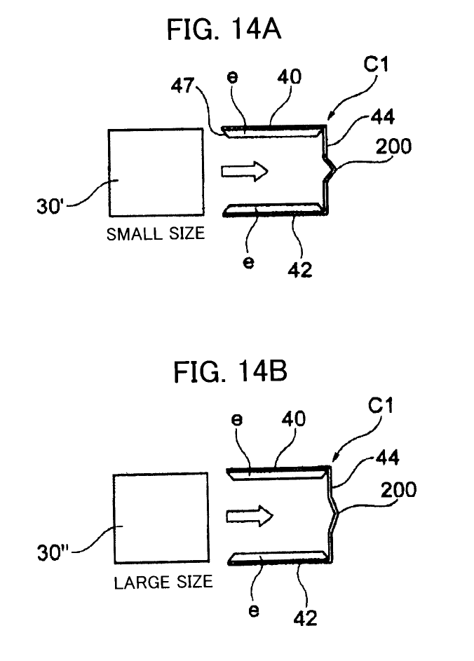

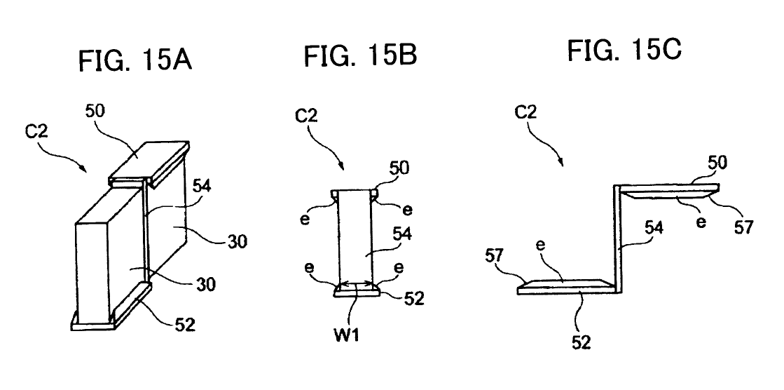

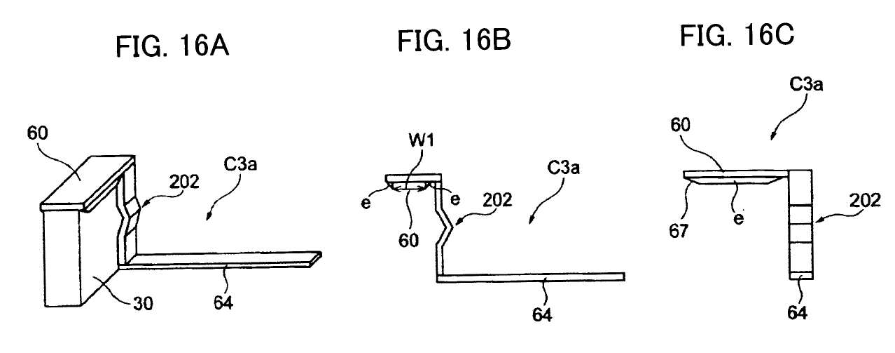

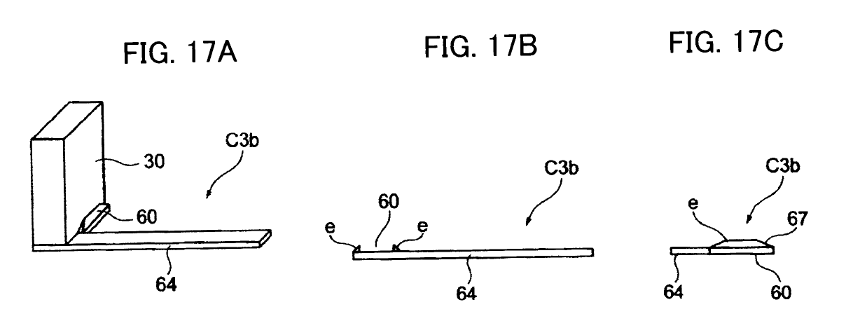

As clearly shown in FIG. 18, in like thermoelectric conversion elements 30 adjoining each other, the first electrode surface (“electrode”) 30a of one element and the second electrode surface (“other electrode”) 30b of another element are electrically connected via a connector C of a predetermined shape. Such a connector C is composed of a first connector C1 (refer to FIG. 12A, FIG. 13, and FIG. 14) of a substantially U-shape (first shape) that electrically connects like thermoelectric conversion elements 30 within each array A1 to A4, and a second connector C2 (refer to FIG. 12B and FIG. 15) of a substantially S-shape (second shape) that electrically connects one thermoelectric conversion element 30 within one array among the arrays A1 and A2 (A2, A3; A3, A4) adjoining each other and one other thermoelectric conversion element 30 within another array. In addition, in the thermoelectric conversion module M, there also exists a different third connector (hereinafter referred to as third connector) C3 (C3a, C3b) (refer to FIG. 16 and FIG. 17) for electrically connecting a first thermoelectric conversion element 30A and a last thermoelectric conversion element 30B of an entire array with external electrodes (“other electrode” not illustrated). It should be noted that silver, brass, SUS and the like, which do not easily rust in a high temperature oxidizing atmosphere, can be exemplified as the material of the connectors C1, C2, and C3.

As shown in FIG. 12A, FIG. 13, and FIG. 14, the first connector C1 has a first fitting portion 40 that is installed by fitting to the first or second electrode face (“electrode”) 30c, 30d of one thermoelectric conversion element 30 disposed on the substrate 90, 91, and a connector lead portion 45 that electrically connectors the first fitting portion 40 to the “other electrode”. In addition, the connector lead portion 45 is composed of a second fitting portion 42 that is installed by fitting to the first or second electrode face 30c, 30d as the “other electrode” of one other thermoelectric conversion element 30 disposed on the substrate 90, 91, and a connecting portion 44 that connects this second fitting portion 42 and the first fitting portion 40. In addition, each of the fitting portions 40 and 42 has at both ends a fold strip e into which the edges of the principal face 30a and 30b insert from both sides. Furthermore, a taper portion 47 that is cutout to incline is provided in both edges of each fold strip e.

In addition, the first connector C1 has an elastically deforming portion 200 for extensibly adjusting the length thereof. This elastically deforming portion 200 is provided by forming the connector lead portion 45, and in particular the connecting portion 44, to bend. More specifically, the elastically deforming portion 200 may be realized by forming the entirety of the connector C1 with a resilient metal (e.g., forming with Ni, Cu, Ag, Au, Pt, etc., where Ni in particular is preferred due to high elasticity and low cost), or may be realized by integrally connecting the elastically deforming portion 200 composed of an elastic material to the connecting portion 44. In addition, in the present embodiment, the elastically deforming portion 200 is formed with a material having a high thermal expansion coefficient (e.g., formed with Ni, Cu, Ag, Au, Pt, etc., where Ni in particular is preferable due to low thermal expansion coefficient) and is made to be elastically deformable so as to absorb the thermal expansion of the connector C1.

Moreover, in the present embodiment, a utilized shape of the substantially U-shape shown in FIG. 13 can be obtained by folding the first connector C1, which is cut out from a plate body in an expanded state shown in FIG. 12A, at a boundary portion of the fitting portions 40 and 42 and the connecting portion 44 at approximately 90 degrees, and folding the fold strip e of both ends of the fitting portions 40 and 42 to at least 90 degrees. Then, when the first fitting portion 40 fits to one first electrode face (“electrode”) 30c among thermoelectric conversion elements 30 and 30 that are adjoining within the same array, and the second fitting portion 42 is fit to another second electrode face (“other electrode”) 30d among the thermoelectric conversion elements 30 and 30 that are adjoining, the connecting portion 44 is directed at an incline from top to bottom, and like thermoelectric conversion elements 30 and 30 that are adjoining are electrically connected. In this case, as shown in FIG. 17, the first connector C1 is installed so that connecting portions 44 in the same array of thermoelectric conversion elements 30 are facing at an incline in the same direction as each other, while being installed so that the direction of the connecting portions 44 between adjoining arrays are reverse (e.g., the inclination direction of the connecting portions 44 within the first array A1 is opposite to the inclination direction of the connecting portions 44 within the second array A2. In addition, the sides to which the connecting portions 44 are positioned toward the principal faces 30a, 30b are all the same inside the same array; however, it is opposite between adjoining arrays. In other words, in the first array A1, the connecting portions 44 are positioned on the side of the side face 30e; however, in the second array A2, the connecting portions 44 are positioned on the side of the side face 30f.

Herein, it should be noted that the installation width W1 (refer to FIG. 13B) of the fitting portions 40 and 41 of the first connector C1 are set to be smaller than the width W2 (refer to FIG. 19) of the electrode sides 30c, 30d of the thermoelectric conversion element 30 by way of folding and inclining the fold strips e at least at 90 degrees. If done in this manner, when the thermoelectric conversion element 30 is fit by pushing into the fitting portions 40 and 42 of the first connector C1, the fitting portions 40 and 42 (fold strips e) are elastically expanded and the electrode sides 30c and 30d of the thermoelectric conversion element 30 can be installed in the fitting portions 40 and 42 of the connector C1 in a one-touch fashion, and since the thermoelectric conversion element 30 and the connector C1 can join without a gap, it is beneficial in that no conduction faults or contact faults occur between the thermoelectric conversion element 30 and the connector C1. In the present embodiment in particular, since the taper portion 47, which is cutout at an incline at both edges of each of the fold strips e, is provided, it is possible to push the thermoelectric conversion element 30 from both edge sides of the fold strips e to slide along the taper shape thereof into the fitting portions 40 and 42, as shown in FIG. 21, and since the fold strips e can be smoothly elastically expanded by way of this, it becomes easy to mount the thermoelectric conversion element 30 to the first connector C1.

In addition, as a configuration for not generating conduction faults and contact faults, since the elastically deforming portion 200 described earlier is provided in the first connector C1 in addition to the fold strips e establishing the folded state described earlier, even if the thermoelectric conversion elements 30′ and 30″ which differ in size are present as shown in FIG. 14 for example, it is possible to allow for compatibility to both the thermoelectric conversion element 30′ and 30″, and a favorable electrical connection can be maintained for both as well.

In other words, in a case of mounting the first connector C1 to the thermoelectric conversion element 30′ of a size smaller than a defined size, the opening width of the first connector (distance between the first fitting portion 40 and the second fitting portion 40) is set to be smaller than a defined width by slightly elastically compressing the elastically deforming portion 200 in a height direction as shown in FIG. 14A, and it is possible to realize an electrical connection not having conductance faults and contact faults by fitting the first connector C1 to the thermoelectric conversion element 30′ without a gap. On the other hand, in a case of mounting the first connector C1 to the thermoelectric conversion element 30″ of a size larger than a defined size, the opening width of the first connector is set to be larger than a defined width by slightly elastically stretching the elastically deforming portion 200 in the height direction as shown in FIG. 14B, and it is possible to realize an electrical connection not having conductance faults and contact faults by fitting the first connector to the thermoelectric conversion element 30″ without a gap.

In addition, as shown in FIGS. 12B and 14, the second connector C2 has a first fitting portion 50 that is installed by fitting to the first or second electrode surface (“electrode”) 30c or 30d of one thermoelectric conversion element 30 placed on the substrate 90 and 91, and a connector lead portion 55 that electrically connects the first fitting portion 50 to an “other electrode”. Moreover, the connector lead portion 55 is composed of a second fitting portion 52 that is installed by fitting to the first or second electrode surface 30c or 30d of another one thermoelectric conversion element 30 placed on the substrates 90 and 91 as the “other electrode”, and a connecting portion 53 that connects the second fitting portion 52 and the first fitting portion 50. Additionally, each of the fitting portions 50 and 52 has fold strips e, into which edges of the principal faces 30a and 30b are inserted from both sides, on both ends. Furthermore, the taper portions 57, which are cut out in order to incline, are provided at both edges of the each fold strip e. In addition, in the present embodiment, a utilized shape of substantially a U-shape as shown in FIG. 15 can be obtained by folding the second connector C2, which is cut from a plate in an expanded state as shown in FIG. 12B, to approximately 90 degrees at a boundary portion of the fitting portions 50 and 52 with the connecting portion 54, and folding the fold strip e of both ends of the fitting portions 50 and 52 to at least 90 degrees. Then, the first fitting portion 50, for example, is fit to the first electrode face (“electrode”) 30c (or, the second electrode face 30d) of one thermoelectric conversion element 30 positioned at an end portion in one array among arrays A1 and A2 (A2 and A3; A3 and A4) adjoining each other, and if the second fitting portion 52 is fit to the second electrode face (“other electrode”) 30d (or, first electrode face 30c) of another one thermoelectric conversion element 30 positioned adjacent to an end portion in another array among the adjoining arrays, the connecting portion 54 is positioned so as to insert between these adjoining thermoelectric conversion elements 30, and these like thermoelectric conversion elements 30 and 30 are electrically connected.

It should be noted that, in the case of the second connector C2 as well, the installation width W1 of the fitting portions 50 and 52 of the connector C2 (refer to FIG. 15B) is set to be smaller than a width W2 of the electrode faces 30c and 30d of the thermoelectric conversion element 30 (refer to FIG. 19) by causing the fold strips e to incline by folding to at least 90 degrees. Therefore, when the thermoelectric conversion element 30 is fit by pushing into the fitting portions 50 and 52 of the second connector C2, the fitting portions 50 and 52 (fold strips e) are elastically expanded and the electrode sides 30c and 30d of the thermoelectric conversion element 30 can be installed in the fitting portions 50 and 52 of the connector C2 in a one-touch fashion, and since the thermoelectric conversion element 30 and the connector C2 can join without a gap, it is beneficial in that no conduction faults or contact faults occur between the thermoelectric conversion element 30 and the connector C2. In the present embodiment in particular, since the taper portion 57, which is cutout at an incline at both edges of each of the fold strips e, is provided, similarly to the first connector C1, it is possible to push the thermoelectric conversion element 30 from both edge sides of the fold strips e to slide along the taper shape thereof into the fitting portions 50 and 52, and since the fold strips e can be smoothly elastically expanded by way of this, it becomes easy to mount the thermoelectric conversion element 30 to the second connector C2.

In addition, as shown in FIG. 12C, the third connector C3 has a first fitting portion 60 that is installed by fitting to the first electrode face 30c (or, second electrode face 30d) of the thermoelectric conversion element 30, and a connector lead portion 64 that extends perpendicularly from an end portion of the first fitting portion 60 and is electrically connected to an external electrode. The fitting portion 60 has fold strips e into which an edge of the principal face 30a (30b) is inserted from both sides. In addition, a taper portion 67, which is cut out to incline, is provided at both edges of each fold strip e.

Moreover, the third connector C3 is divided into a connector C3a (refer to FIG. 16) for electrically connecting a first thermoelectric conversion element 30A of an entire array (refer to FIG. 17) and an external electrode (“other electrode”, not illustrated), and a connector C3b (refer to FIG. 17) for electrically connecting a last thermoelectric conversion element 30B of an entire array (refer to FIG. 17); however, both of the connectors C3a and C3b can also be formed from the connector C3 cut from a plate in the expanded state shown in FIG. 12C.

In other words, in the present embodiment, when the third connector C3, which is cut from a plate in the expanded state shown in FIG. 12C, is folded to approximately 90 degrees at a boundary portion of the fitting portion 60 and the connector lead portion 64 and folded to approximately 90 degrees at a middle portion 69 of the connector lead portion 64, and the fold strips e of both ends of the fitting portion 60 are folded to at least 90 degrees, it is possible to obtain the connector C3a for electrically connecting the first thermoelectric conversion element 30A of an entire array and an external electrode (“other electrode”, not illustrated) as shown in FIG. 16. On the other hand, when the third connector C3, which has been cut from a plate in the expanded sate shown in FIG. 12C, is folded to approximately 90 degrees at a boundary portion of the fitting portion 60 and the connector lead portion 64, and the fold strips e of both ends of the fitting portion 60 are folded at least 90 degrees, it is possible to obtain the connector C3b for electrically connecting the last thermoelectric conversion element 30B of an entire array and an external electrode (“other electrode”, not illustrated) as shown in FIG. 17. Then, when the fitting portion 60 of the connector C3a and connector C3b fit to the first or second electrode face 30c (30d) of the first and last thermoelectric conversion elements 30A and 30B of an entire array, and the connector lead portion 64 is connected to an external electrode, the thermoelectric conversion module M and an external device (or, external element, external circuit) are electrically connected.

It should be noted that, in the case of the third connector C3 as well, the installation width W1 of the fitting portion 60 of the connector C3 (refer to FIG. 15B) is set to be smaller than a width W2 of the electrode faces 30c and 30d of the thermoelectric conversion element 30 (refer to FIG. 18) by causing the fold strips e to incline by folding to at least 90 degrees. In addition, even in the case of the third connector C3, similarly to the first connector C1, an elastically deforming portion 202 provided in a form similar to the elastically deforming portion 200 is provided to a portion in the vicinity of the fitting portion 60 of the connector lead portion 64. However, the elastically deforming portion 202 is substantially functional in a case of forming the connector C3a for electrically connecting the first thermoelectric conversion element 30A of an entire array and an external electrode.

Incidentally, as one mode of the present embodiment, the arrays A1, A2, A3, and A4 of the thermoelectric conversion elements 30 electrically connected to each other are formed by fixing each of the connectors C1, C2, and C3 beforehand in a predetermined array on the substrate 90 (and/or substrate 91), and mounting each of the thermoelectric conversion elements 30 by inserting to the fixing portions 40, 42, 50, 52, and 60 of these connectors C1, C2, and C3. Naturally, it may also be made so that each of the connectors C1, C2, and C3 are separately fit beforehand to the thermoelectric conversion elements 30, and the thermoelectric conversion elements 30 with the connector formed in this way are installed in a predetermined array on the substrates 90 and 91.

In the thermoelectric conversion module M of the above such configuration, heat energy generated between the high temperature portion and the low temperature portion of each of the thermoelectric conversion elements 30 is converted to electric energy. Then, the electric energy thus obtained is supplied as electric power to the external electrode via the connector lead portion 64.

As explained above, the thermoelectric conversion module M according to the present embodiment is characterized in being a thermoelectric conversion module made by disposing thermoelectric conversion elements 30 on the substrate 91, and electrically connecting electrodes of the thermoelectric conversion elements 30 and other electrodes that are different from the electrode via connectors C of a predetermined shape having electrical conductivity, and having elastically deforming portions 200 and 202 for extensibly adjusting the length of the connector C (C1 and C3a in the present embodiment). Therefore, according to such a thermoelectric conversion module M, it is possible to mechanically and electrically connect the connectors C (C1, C3a) to elements 30 of various sizes reliably by absorbing the difference in size of the elements 30 with the elastically deforming portions 200 and 202 (conductance faults accompanying differences in element size can be prevented). In other words, even if the elements 30 differ in size, this is handled without discarding material, and as a result, it is possible to reduce the manufacturing cost and to decrease the negative impact on the environment compared to conventionally. In addition, since the elements 30 can be easily attached and detached from the connector due to the elastically deforming portions 200 and 202 even when an element 30 is damaged, not only the ease of manufacture, but also the maintainability is superior. Moreover, it is possible to absorb deformation of the connector C, not only for differences in element size, but also due to thermal expansion of the elements 30 with the elastically deforming portions 200 and 202, and thus electrical contact faults accompanying thermal expansion of the elements 30 can also be avoided.

Furthermore, in the present embodiment, the electrical characteristics of each of the thermoelectric conversion elements 30 can be made uniform by configuring the thermoelectric conversion elements 30 with the same raw materials (e.g., same size, same shape, same materials (same conductivity type semiconductor, etc.)). As a result, it is possible to improve the thermoelectric conversion efficiency compared with conventional thermoelectric conversion modules made by disposing like elements having different conductivity type, for example, to be alternating. Then, in this structure in which like raw materials of identical type are combined, the elastically deforming portions 200 and 202 of the present embodiment, which are made so as to absorb differences in element size, are more beneficial compared to a structure combining different types (p-type and n-type) elements as disclosed in Japanese Unexamined Patent Application Publication No. H01-179376 described earlier in which element size is essentially involved in electrical characteristics, whereby a large practical value can be found.

In addition, in the present embodiment, like thermoelectric conversion elements 30 adjoining each other are electrically connected via the connectors C1 and C2 of a predetermined shape fit to the first electrode face 30c of one element and the second electrode face 30d of another element. In this way, in place of a conventional lead wire for connection, the connectors (a connector integrating a conventional lead wire for connection and a fitting portion) C1 and C2 are used so that the lead wires are so-called integrally inserted, and when like thermoelectric conversion elements 30 are electrically connected by these connectors C1 and C2, a thermoelectric conversion module M can be provided having high electrical reliability without conductance faults.

In this case, as described earlier, each of the connectors C1, C2, and C3 are fixed beforehand in a predetermined array on the substrate 90 (and/or substrate 91), and if done so as to form the arrays A1, A2, A3, and A4 of thermoelectric conversion elements 30 electrically connected together by installing each of the thermoelectric conversion elements 30 by inserting to the fitting portions 40, 42, 50, 52, and 60 of these connectors C1, C2, and C3, it is possible to reduce the assembly labor (manufacturing process) (improve assembly properties) since a simple thermoelectric conversion module can be developed.

In addition, in the present embodiment, the thermoelectric conversion elements 30 are disposed to stand up vertically so that the electrode faces 30c and 30d thereof face the substrates 90 and 91 and the principal faces 30a and 30b thereof are substantially perpendicular to the substrates 90 and 91. When arranged in this way in a state in which the thermoelectric conversion elements 30 are standing vertically, as explained earlier in the introduction of the present embodiment, the dimension in the height direction of the thermoelectric conversion element 30 becomes large, the element resistance becomes large and thus the electric current is suppressed, while a temperature differential between both end elements becomes easily achieved, electromotive force raises, and thus it becomes possible to obtain high thermoelectric conversion efficiency.

In addition, in the thermoelectric conversion module M of the present embodiment, the arrays A1 to A4 of the thermoelectric conversion elements 30 are sandwiched between a pair of substrates 90 and 91. In this way, when the thermoelectric conversion elements 30 are fixed so that pressure is applied from both sides by sandwiching the arrays A1 to A4 of the thermoelectric conversion elements 30 with the pair of substrates 90 and 91, conduction faults and contact faults can be reduced, and it is possible to improve the electrical reliability since the contact surface area between the electrode faces 30a and 30b of the thermoelectric conversion element 30 and the connectors C1, C2, and C3 becomes large.

In addition, in the thermoelectric conversion module M of the present embodiment, it becomes possible to use the three types of connectors C1, C2, and C3 having corresponding appropriate shapes according to the electrical connection position thereof. As a result, thermoelectric conversion arrays of various forms according to the application can be realized since it is possible to modularize vertical thermoelectric conversion elements 30 with good connectivity as well as good efficiency, while being able to use connectors for different purposes according to the connection configuration of the thermoelectric conversion element 30.

In addition, in the thermoelectric conversion module M of the present embodiment, it is possible to improve the heat resistances and mechanical strength since the thermoelectric conversion elements 30 are formed with a sintered body of a complex metal oxide. In the present embodiment in particular, it is possible to further improve the heat resistance at high temperature by making an oxide of the complex metal elements be an oxide in which alkali earth metal, rare earths, and manganese are the constituent elements.

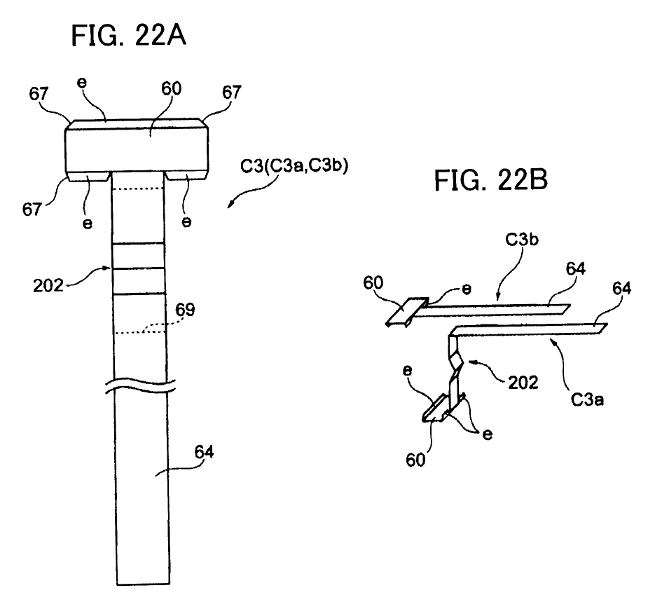

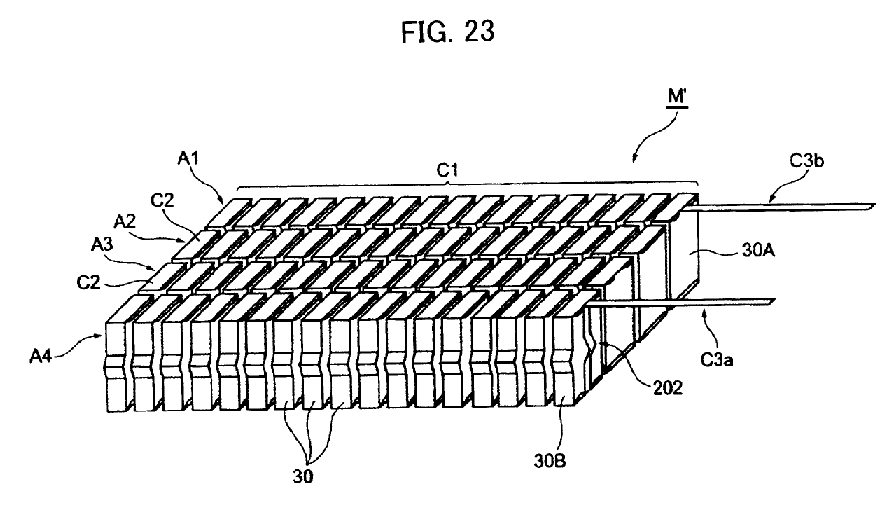

It should be noted that the present invention is not limited to the embodiments described above, and naturally can be implemented by making various modifications within a scope not departing from the spirit thereof. For example, in the embodiment described above, a plurality of semiconductor elements of the same conduction type are provided to make predetermined arrays and a module configuration made by connecting like electrodes located on both faces of these semiconductor elements by way of connectors is given as one example; however, the present invention can also be employed in a module configuration in which n-type semiconductor elements and p-type semiconductor elements are disposed alternately on a substrate and like semiconductor elements that are adjoining are connected by electrodes. In addition, the shape of the connectors is also not limited to the embodiment described above. For example, if giving a modified example relating to the third connector C3, a shape may also be considered in which the connector lead portion 64 extends from the center of the first fitting portion 60 as shown in FIG. 22A. In such a shape, two types of connectors C3a and C3b can be obtained as shown in FIG. 22B depending on the existence of a fold in the middle portion 69, and as shown in FIG. 23, for example, from this it is possible for the connector lead portion 64 to extend from the first thermoelectric conversion element 30A and from the last thermoelectric conversion element 30B of an entire array in the same level plane in order to conform to the positional relationship of an external electrode.

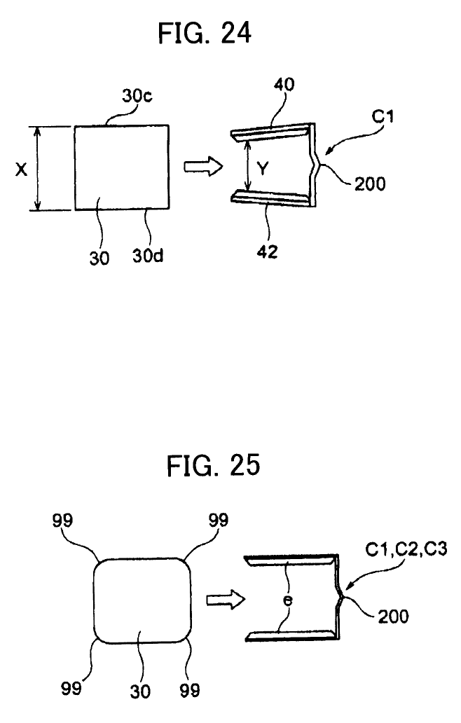

In addition, in the embodiment described above, a distance between like fitting portions of connectors fitting both sides of a thermoelectric conversion element together in a state in which the thermoelectric conversion element is not installed in the connector may be shorter than a distance between electrodes of the thermoelectric conversion element. More specifically, for the first connector C1 in the array A1 shown in FIG. 20, for example, although one connector C1 having a first fitting portion 40 fitting the first electrode face 30c and the other connector having the second fitting portion 42 fitting the second electrode face 30d can have the thermoelectric conversion element 30 inserted by adjoining like fitting portions 40 and 42 thereof to be facing, in this case, the distance Y between the first fitting portion 40 of one of the first connectors C1 and the second fitting portion 40 of the other first connector C1 adjoining in a state in which the thermoelectric conversion element 30 is not installed as shown in FIG. 24 may be set to be shorter than a distance X between the first electrode face 30c and the second electrode face 30d of the thermoelectric conversion element 30.

If done in this way, when the thermoelectric conversion element 30 is fitted to the connector C1 of a substantially U-shape having tips narrowing, the thermoelectric conversion element 30 is fitted by expanding the tips of the fitting portions 40 and 42. As a result, since the tips of the fitting portions 40 and 42 push the thermoelectric conversion element 30, it is possible to reliably retain the thermoelectric conversion element 30 with the connector C1. In addition, when mounting the thermoelectric conversion element 30, the fitting portions 40 and 42 facing each other become substantially parallel, and it is possible to make the contact surface area between the electrode faces 30c and 30d and the fitting portions 40 and 42 at the connector C1 to be uniform in the thermoelectric conversion module. As a result, the thermoelectric efficiency can be improved. Naturally, such a configuration can also be employed for the second and third connectors C2 and C3.

In addition, in the embodiment described above, in order to facilitate insertion and fitting of the thermoelectric conversion elements 30 to the connectors C1, C2, and C3, as shown in FIG. 25, the edges 99 of the thermoelectric conversion element 30 may be slightly rounded. In other words, the edges 99 of the thermoelectric conversion element 30 may be made a bevel R at a predetermined curvature. If configured in this way, it becomes difficult for the thermoelectric conversion element 30 to catch when inserting to the connectors C1, C2, and C3, and thus the thermoelectric conversion element 30 can be smoothly inserted to the connectors C1, C2, and C3. It should be noted that the shape of such a thermoelectric conversion element 30 can be simply realized by changing the die when molding.

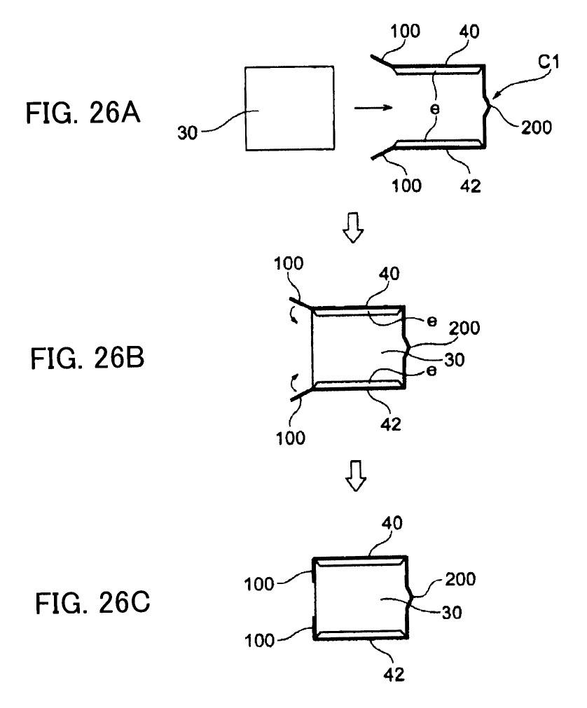

In addition, from the point of view that the insertion property of the thermoelectric conversion element 30 to the connectors C1, C2, and C3 is raised, a configuration as shown in FIG. 26 has also been considered. In other words, FIG. 26 shows the first connector C1 as one example; however, in this case, the first fitting portion 40 and the second fitting portion 42 have guiding portions 100 at the edges thereof that can fold inwards (refer to FIGS. 26B and C) so as to follow the thermoelectric conversion element 30 after mounting of the thermoelectric conversion element 30 has been guided and the thermoelectric conversion element 30 has been mounted to the fitting portions 40 and 42. This guiding portion 100 is made a strip shape, and extends so as to widen toward the outer side.

In this way, so long as the fitting portions 40 and 42 have the guiding portions 100, the assembly efficiency can be improved since it becomes easy to mount the thermoelectric conversion elements 30 to the connector C1 (particularly, the effect in the case of setting the installation width of the fitting portion of the connector to be smaller than the width of the electrodes of the thermoelectric conversion element is great (e.g., configuration of FIG. 24)). In addition, by way of the guiding portions 100 being able to fold so as to follow the thermoelectric conversion element 30, it is possible to fix the thermoelectric conversion element at the guiding portion 100 after having mounted the thermoelectric conversion element 30 to the connector C1 (refer to FIG. 26C), and thus it is possible to improve the mounting stability of the thermoelectric conversion element 30 to the connector C1. Therefore, it is possible to provide a thermoelectric conversion module having high electrical reliability without conduction faults. Naturally, such a configuration can be applied to the second and third connectors C2 and C3 as well.

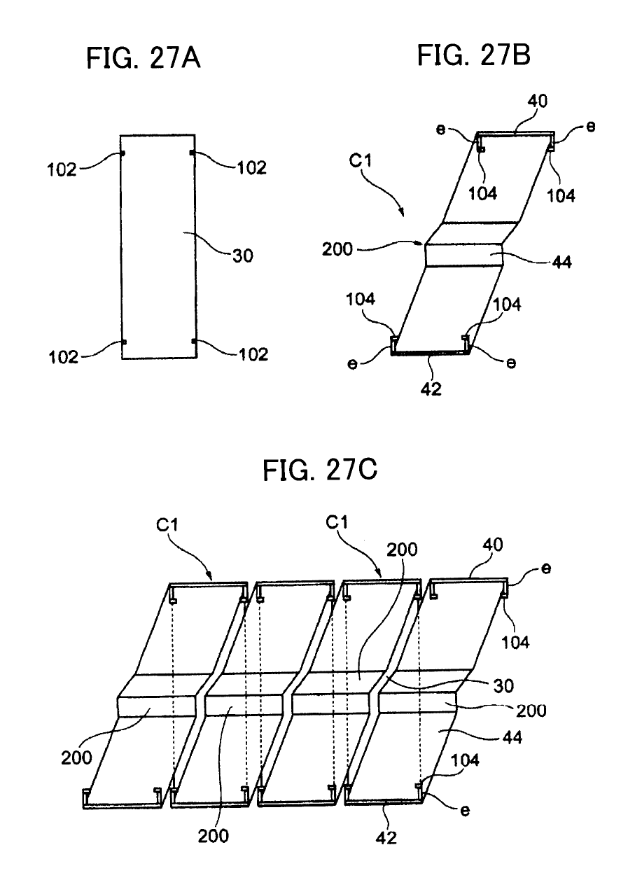

In addition, from the point of view of improving the mounting stability of the thermoelectric conversion elements to the connectors, the configuration shown in FIG. 27 has also been considered. In other words, FIG. 27 shows the first connector C1 as one example; however, in this case, the first fitting portion 40 and the second fitting portion 42 (more specifically, each of the fold strips e) have an engaging portion 104 (refer to FIG. 27B) of a hook shape that is engaged in a fixing groove 102 (refer to FIG. 27A) formed on both upper and lower sides of the thermoelectric conversion element 30. If done in this way, a thermoelectric conversion module can be provided that can improve mounting stability while having high electrical reliability without conduction faults, since the thermoelectric conversion elements 30 are mounted firmly to connectors C1 by way of engaging the engaging portion 104 of the connector C1 to the fixing groove 102 of the thermoelectric conversion element 30 when mounting (refer to FIG. 27C). Naturally, such a configuration can also be applied to the second and third connectors C2 and C3 as well.

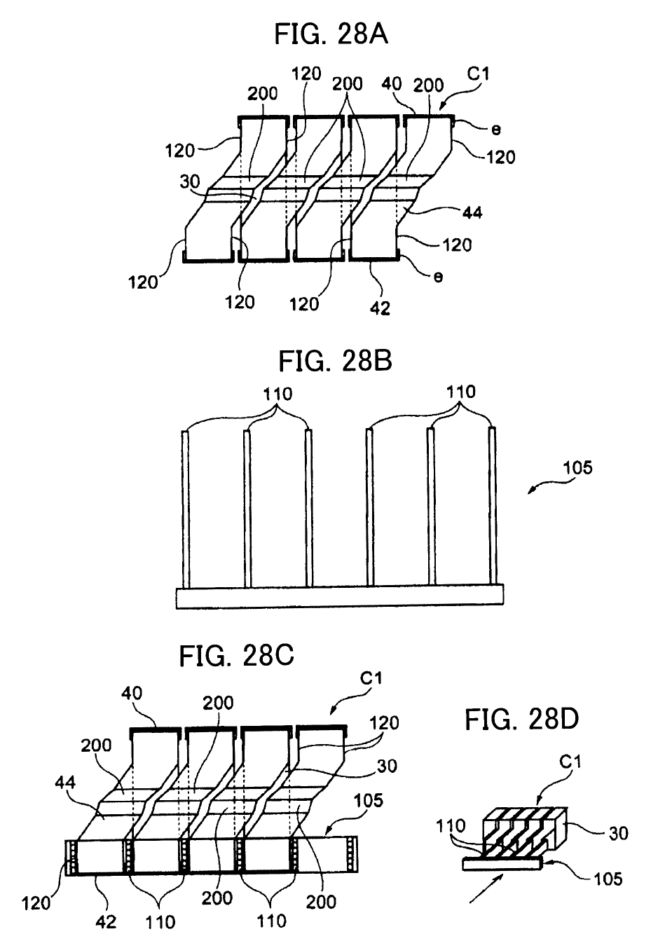

In addition, from the point of view of improving the mounting stability of the thermoelectric conversion elements in the connectors, a configuration as shown in FIG. 28 has also been considered. In other words, FIG. 28 shows the first connector C1 as one example; however, in this case, the connecting portion 44 configuring the connector lead portion has a parallel portion 120 on both upper and lower sides in side faces between the electrode faces 30c and 30d of the thermoelectric conversion element 30 that extends from the electrode faces 30c and 30d, as shown in FIG. 28A. The contact surface area between the connector lead portion (connecting portion 44) and the thermoelectric conversion element 30 becomes large by the connector lead portion having such a parallel portion 120, and thus it is possible to retain the thermoelectric conversion element 30 with a larger surface area, and it is possible to improve the mounting stability of the thermoelectric conversion element 30 in the connector C1.

It should be noted that, in addition to the present constitution or apart therefrom, a fixing member 105 including comb-teeth 110 that can be inserted into both sides of the thermoelectric conversion element 30, as shown in FIG. 28B, and have electrical insulating property may be provided in order to ensure additional mounting stability. When such a fixing member 105 including comb-teeth 110 is provided, the comb-teeth 110 are inserted into both sides of one or a plurality of thermoelectric conversion elements 30 (refer to FIGS. 28C and D), the thermoelectric conversion elements 30 are supported by way of the comb-teeth 110, and it is possible to improve the mounting stability of the thermoelectric conversion elements 30 in the module. In addition, since the fixing member 105 has an electrical insulating property to prevent short-circuiting, electrical insulation can be at a lateral side of the thermoelectric conversion elements 30 where like thermoelectric conversion elements 30 are exposed and face each other (preventing short-circuiting of like thermoelectric conversion elements 30), which is particularly advantageous. It should be noted that, in this case, it is preferred that, if mounting the fixing member 105 to the cooling face side (low temperature side), for example, an anodization treatment of aluminum (alumite treatment) is conducted on the fixing member 105, and if mounting the fixing member 105 on the heating face side (high temperature side), that stainless (SUS) is deposited on the fixing member 105 by way of PVD (physical vapor deposition), and glass coating is performed.

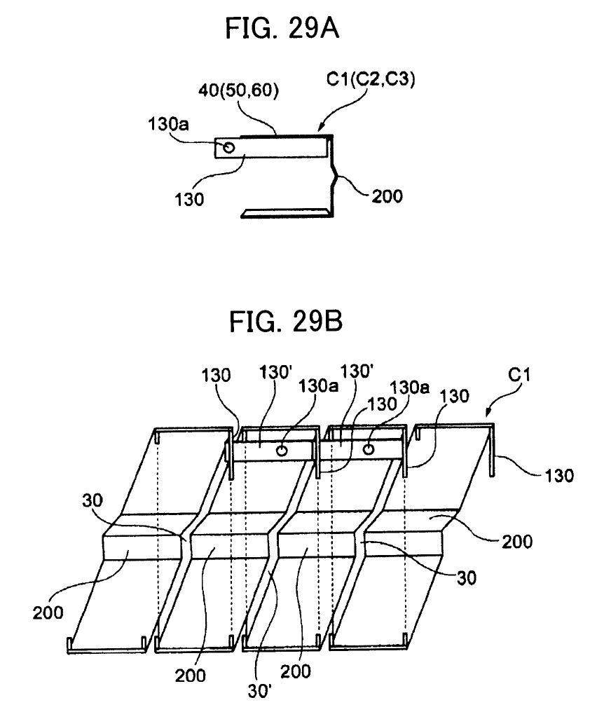

In addition, in the embodiment described above, such a configuration as shown in FIG. 29 can also be added. In other words, in the configuration shown in FIG. 29, the first fitting portions 40, 50, and 60 (naturally, may also be the second fitting portions) of the connectors C1, C2, and C3 have a strip for short-circuiting 130 that can be folded and has sufficient length in order to electrically contact with an adjacent connector when folded. This strip for short-circuiting 130 is adhered to the fold strip e and extends along the fold strip e, for example, and a penetrating hole 130a into which a short-circuit line for repair (e.g., a wire) penetrates is further provided in the extending portion that extends by a predetermined length from an end edge of the fold strip e.

With such a constitution, as shown in FIG. 29B, in a case in which one of the thermoelectric conversion elements 30′ is damaged or deteriorated to cause a conduction fault between the connector C1, the strip for short-circuiting 130 on both sides of the thermoelectric conversion element 30′ is folded and, using the fold portion 130′ thereof, like thermoelectric conversion elements 30 and 30 on both sides of the thermoelectric conversion element 30′ are electrically short-circuited by the short-circuit line for repairing. In this way, by providing the strip for short-circuiting 130 to each connector in advance, it is possible to easily repair the thermoelectric conversion element by conducting between connectors without performing a difficult operation such as replacement, even when any of the thermoelectric conversion elements are damaged (deteriorated).

1. A thermoelectric conversion module made by disposing thermoelectric conversion elements on a substrate, and electrically connecting an electrode of the thermoelectric conversion element with an other electrode that is different from the electrode via a connector of a predetermined shape having electrical conductivity,
wherein the connector comprises an elastically deforming portion for extensibly adjusting a length thereof.

2. The thermoelectric conversion module according to claim wherein the elastically deforming portion is provided by forming the connector to bend.

3. The thermoelectric conversion module according to claim 2, wherein the elastically deforming portion is elastically deformable so as to absorb thermal expansion of the connector.

4. The thermoelectric conversion module according to claim 3, wherein the connector further comprises:
a first fitting portion that is installed by fitting on an electrode of the thermoelectric conversion element; and
a connector lead portion that is electrically connected to the first fitting portion and the other electrode.

5. The thermoelectric conversion module according to claim 4, wherein the elastically deforming portion is provided to the connector lead portion.

6. The thermoelectric conversion module according to claim 5, wherein each of the thermoelectric conversion elements contains the same material.

7. The thermoelectric conversion module according to claim 6, wherein the thermoelectric conversion element includes a principal surface having the largest surface area, while electrodes are respectively positioned at both sides of the principal surface, and is disposed to be standing vertically so that the electrodes are opposing the substrates and the principal faces are substantially perpendicular to the substrates.

8. The thermoelectric conversion module according to claim 7, wherein the connector is fixed in advance in a predetermined array on the substrate.

9. The thermoelectric conversion module according to claim 8, wherein the electrodes of the thermoelectric conversion element include a pair of a first electrode and a second electrode that is positioned on both sides of the thermoelectric conversion element, and
wherein the thermoelectric conversion element is sandwiched between a first substrate opposing the first electrode and a second substrate opposing the second electrode.

10. The thermoelectric conversion module according to claim 9, wherein the other electrode is an external electrode to which the thermoelectric conversion module is electrically connected.

11. The thermoelectric conversion module according to claim 10, wherein the first fitting portion includes a guiding portion that guides installation of the thermoelectric conversion element, and that is bendable so as to follow the thermoelectric conversion element after the thermoelectric conversion element has been installed in the first fitting portion.

12. The thermoelectric conversion module according to claim 11, wherein the first fitting portion includes a strip for short-circuiting that is bendable and has sufficient length to electrically connect with a connector adjacent thereto when bent.

13. The thermoelectric conversion module according to claim 12, wherein the connector lead portion has a second fitting portion that is installed by fitting to an other electrode of an other thermoelectric conversion element disposed on the substrate.

14. The thermoelectric conversion module according to claim 13, wherein the connector lead portion has a parallel portion on a side face between electrode faces of the thermoelectric conversion element that extends from the electrode face.

15. The thermoelectric conversion module according to claim 14, comprising a fixing member including comb-teeth that can be inserted into both sides of the thermoelectric conversion element and have an electrical insulating property.

16-19. (canceled)

20. A connector for thermoelectric conversion elements to electrically connect an electrode of the thermoelectric conversion element to an other electrode, the connector comprising an elastically deforming portion for extensibly adjusting a length of the connector.

21. The connector for thermoelectric conversion elements according to claim 20, wherein the elastically deforming portion is provided by forming the connector to bend.

22. The connector for thermoelectric conversion elements according to claim 21, wherein the elastically deforming portion is elastically deformable so as to absorb thermal expansion of the connector.

23. The connector for thermoelectric conversion elements according to claim 22, wherein the connector further comprises:
a first fitting portion that is installed by fitting to an electrode of the thermoelectric conversion element; and
a connector lead portion that is electrically connected to the first fitting portion and the other electrode.

24. The connector for thermoelectric conversion elements according to claim 23, wherein the elastically deforming portion is provided to the connector lead portion.
